(19) United States
(12) Patent Application Publication
(10) Pub. No.: US 2026/0247788 A1
(43) Pub. Date: Aug. 20, 2026

(54) QUANTUM DOT DISPLAY PANEL, ELECTRONIC DEVICE INCLUDING THE SAME, AND METHOD OF OPERATING THE SAME

(71) Applicant: SAMSUNG ELECTRONICS CO., LTD., Suwon-si (KR)

(72) Inventors: Moon Gyu HAN, Suwon-si (KR); Tae-Gon KIM, Suwon-si (KR); Taehyung KIM, Suwon-si (KR); Taekhoon KIM, Suwon-si (KR); Kyung Bae PARK, Suwon-si (KR); Dae-Yong Son, Suwon-si (KR); Nayoun WON, Suwon-si (KR); Shin Ae JUN, Suwon-si (KR)

(21) Appl. No.: 19/536,380

(22) Filed: Feb. 11, 2026

(30) Foreign Application Priority Data
Feb. 17, 2025 (KR) 10-2025-0019957

(51) Int. Cl. H10K 50/115

(52) U.S. Cl. CPC H10K 50/115

(57) ABSTRACT

A quantum dot display panel of an electronic device includes a quantum dot light emitting diode which emits light in wavelength range, and a quantum dot sensor which is adjacent to the quantum dot light emitting diode and absorbs light in a visible light to infrared light wavelength range.

### CROSS-REFERENCE TO RELATED APPLICATION

This application claims priority to Korean Patent Application No. 10-2025-0019957 filed with the Korean Intellectual Property Office on Feb. 17, 2025, and all the benefits accruing therefrom under 35 U.S.C. § 119, the entire contents of which are incorporated herein by reference.

### BACKGROUND

### 1. Field

A quantum dot display panel, an electronic device including the same, and a method of operating the same are disclosed.

### 2. Description of the Related Art

Quantum dots may emit light of a wavelength corresponding to a size of the quantum dot when supplied with optical energy or electrical energy. Accordingly, quantum dots may be used as light emitter configured to emit light of a predetermined wavelength by controlling their size. These quantum dots may be applied to display panels which display colors.

### SUMMARY

An embodiment provides a quantum dot display panel capable of performing additional functions in addition to the function of displaying color.

An embodiment provides an electronic device including the quantum dot display panel.

An embodiment provides a method of operating the electronic device.

According to an embodiment, a quantum dot display panel includes a first quantum dot light emitting diode including a first quantum dot layer emitting light in a red wavelength region, a second quantum dot light emitting diode including a second quantum dot layer emitting light in a green wavelength region, a third quantum dot light emitting diode including a third quantum dot layer emitting light in a blue wavelength region, and a quantum dot sensor including a fourth quantum dot layer absorbing light in at least a portion of a visible to infrared wavelength region.

The quantum dot display panel may further include a substrate, and the first, second, and third quantum dot light emitting diodes and the quantum dot sensor may be arranged in a parallel manner along an in-plane direction of the substrate.

The first, second, and third quantum dot light emitting diodes may further include a first, second, or third pixel electrode under the first, second, or third quantum dot layer, the quantum dot sensor may further include a fourth pixel electrode under the fourth quantum dot layer, the first, second, and third quantum dot light emitting diodes and the quantum dot sensor may further include a common electrode connected to each other and formed continuously on the first, second, third, and fourth quantum dot layers, the first, second, third, and fourth pixel electrodes may be arranged in a parallel manner along the in-plane direction of the substrate, and the first, second, third, and fourth quantum dot layers are arranged in a parallel manner along the in-plane direction of the substrate.

The first, second, and third quantum dot light emitting diodes and the quantum dot sensor may further include a first common auxiliary layer formed between the first, second, third, and fourth pixel electrodes and the first, second, third, and fourth quantum dot layers and connected to each other and continuously formed, and a second common auxiliary layer formed between the common electrodes and the first, second, third, and fourth quantum dot layers and connected to each other and continuously formed.

The second common auxiliary layer may include inorganic nanoparticles represented by Zn₁₋ₓQₓO (where, Q is Be, Mg, Ca, Ba, Sr, Ra, or a combination thereof, and 0≤x<0.5).

The quantum dot display panel may include a plurality of first sub-pixels displaying red, a plurality of second sub-pixels displaying green, a plurality of third sub-pixels displaying blue, and a fourth sub-pixel sensing light, each of the first sub-pixels may include the first quantum dot light emitting diode, each of the second sub-pixels may include the second quantum dot light emitting diode, the each of the third sub-pixels may include the third quantum dot light emitting diode, and each of the fourth sub-pixels may include the quantum dot sensor, at least one of the first sub-pixels, at least one of the second sub-pixels, and at least one of the third sub-pixels may form one unit group and be repeatedly arranged along an in-plane direction of the substrate, and at least a portion of the repeatedly arranged unit groups may further include at least one of the fourth sub-pixels.

The quantum dot display panel may further include a fourth quantum dot light emitting diode including a fifth quantum dot layer which emits light in the infrared wavelength region.

The quantum dot display panel may include a quantum dot sensor array including a plurality of the quantum dot sensors, and a quantum dot light emitting diode array including the first, second, and third quantum dot light emitting diodes, and the quantum dot sensor array and the quantum dot light emitting diode array may be stacked on each other.

The quantum dot display panel may further include a substrate supporting the quantum dot light emitting diode array, and the first, second, and third quantum dot light emitting diodes may further include a first, second, or third pixel electrode under the first, second, or third quantum dot layer, and a first common electrode on the first, second, or third quantum dot layer, the quantum dot sensor may further include a fourth pixel electrode under the fourth quantum dot layer, and a second common electrode on the fourth quantum dot layer, and the fourth quantum dot layer may overlap with the first, second, or third quantum dot layer along a thickness direction of the substrate.

The fourth quantum dot layer may be configured to detect light in at least a portion of a red to infrared wavelength region.

The quantum dot light emitting diode array may further include a fourth quantum dot light emitting diode including a fifth quantum dot layer which emits light in the infrared wavelength region.

The quantum dot display panel may further include an optical filter between the quantum dot light emitting diode array and the quantum dot sensor array.

The quantum dot sensor may include a fingerprint sensor, a biometric signal detection sensor, a bioimaging sensor, a distance sensor, a motion sensor, or a combination thereof.

According to an embodiment, an electronic device includes a quantum dot display panel, a gate driver for generating a gate signal and outputting the gate signal to the quantum dot display panel, and a data driver for outputting a data voltage to the quantum dot display panel, where the quantum dot display panel includes a first quantum dot light emitting diode including a first quantum dot layer for emitting light in a red wavelength region, a second quantum dot light emitting diode including a second quantum dot layer for emitting light in a green wavelength region, a third quantum dot light emitting diode including a third quantum dot layer for emitting light in a blue wavelength region, and a quantum dot sensor including a fourth quantum dot layer for absorbing light in at least a portion of a visible to infrared wavelength region.

The first, second, and third quantum dot light emitting diodes and the quantum dot sensor may be arranged side by side along the in-plane direction of the substrate, or the quantum dot sensor may overlap with the first, second or third quantum dot light emitting diode along the thickness direction of the substrate.

The electronic device may further include a light source which supplies light in the infrared wavelength region.

According to an embodiment, a method of operating an electronic device includes driving at least one of a first quantum dot light emitting diode including a first quantum dot layer emitting light in a red wavelength region, a second quantum dot light emitting diode including a second quantum dot layer emitting light in a green wavelength region, and a third quantum dot light emitting diode including a third quantum dot layer emitting light in a blue wavelength region, and driving a quantum dot sensor including a fourth quantum dot layer absorbing light in at least a portion of a visible to infrared wavelength region, where the driving of at least one of the first, second, and third quantum dot light emitting diodes and the driving of the quantum dot sensor are performed simultaneously or sequentially.

The driving of at least one of the first, second, and third quantum dot light emitting diodes may include supplying light to a user's recognition target, and the driving of the quantum dot sensor may include sensing light reflected by the user's recognition target.

The method may further include comparing an image of the user's recognition target obtained by detecting the reflected light with a pre-stored contrast image, and driving at least one of the first, second, and third quantum dot light emitting diodes to display an image when the image of the user's recognition target matches the contrast image.

The method may further include turning on a light source to supply light in an infrared wavelength region to a subject, and measuring a time or distance at which the supplied light is reflected by the subject and detected by the quantum dot sensor. The quantum dot display panel may perform both self-luminous display functions and user interaction functions without requiring complex structures and processes.

### BRIEF DESCRIPTION OF THE DRAWINGS

FIG. 1 is a plan view schematically showing an example of a quantum dot display panel according to an embodiment,

FIG. 2 is a cross-sectional view taken along line II-II of the quantum dot display panel of FIG. 1,

FIG. 3 is an optical spectrum showing an example of luminescence and light-absorption characteristics of the first, second, and third quantum dot light emitting diodes and the quantum dot sensor in the quantum dot display panels of FIGS. 1 and 2,

FIGS. 4A and 4B are schematic views showing an example of a fingerprint sensor using the quantum dot display panel of FIGS. 1 and 2,

FIGS. 5A and 5B are schematic views showing an example of a biometric signal detection sensor using the quantum dot display panel of FIGS. 1 and 2,

FIGS. 6A and 6B are schematic views showing an example of a distance sensor using the quantum dot display panels of FIGS. 1 and 2,

FIG. 7 is a plan view schematically showing another example of a quantum dot display panel according to an embodiment,

FIG. 8 is a cross-sectional view taken along line VIII-VIII of the quantum dot display panel of FIG. 7,

FIGS. 9A and 9B are plan views schematically showing another example of a quantum dot display panel according to an embodiment,

FIG. 10 is a cross-sectional view taken along the X-X line of the quantum dot display panel of FIG. 9B,

FIG. 11 is a cross-sectional view showing an example of a quantum dot light emitting diode array in the quantum dot display panel of FIGS. 9A, 9B and 10,

FIG. 12 is a cross-sectional view showing an example of a quantum dot sensor array in the quantum dot display panel of FIGS. 9A, 9B and 10,

FIG. 13 is an optical spectrum showing an example of the luminescence and light-absorption characteristics of the quantum dot light emitting diode array and the quantum dot sensor array in the quantum dot display panel of FIGS. 9A, 9B and 10,

FIGS. 14A and 14B are schematic views showing an example of a fingerprint sensor using the quantum dot display panel of FIGS. 10 and 11,

FIGS. 15A and 15B are schematic views showing an example of a biometric signal detection sensor using the quantum dot display panel of FIGS. 10 and 11,

FIGS. 16A and 16B are schematic views showing an example of a distance sensor using the quantum dot display panels of FIGS. 10 and 11,

FIGS. 17A and 17B are plan views schematically showing another example of a quantum dot display panel according to an embodiment,

FIG. 18 is a cross-sectional view taken along line XVIII-XVIII of the quantum dot display panel of FIG. 17B.

FIG. 19 is a cross-sectional view showing an example of a quantum dot light emitting diode array in the quantum dot display panel of FIGS. 17A, 17B and 18,

FIG. 20 is a block diagram showing an example of an electronic device according to an embodiment of the present invention,

FIG. 21 is a graph showing external quantum efficiency according to wavelength of a quantum dot sensor according to Example 2.

### DETAILED DESCRIPTION

Hereinafter, embodiments will be described in detail so that those of ordinary skill in the art may easily implement them. However, the structure that is actually applied may be implemented in various different forms and is not limited to the embodiments described herein.

In the drawings, the thickness of layers, films, panels, regions, etc., are exaggerated for clarity. It will be understood that when an element such as a layer, film, region, or substrate is referred to as being related to another element such as being “on” another element, it may be directly on the other element or intervening elements may also be present. In contrast, when an element is referred to as being related to another element such as being “directly on” another element, there are no intervening elements present.

In the drawings, parts having no relationship with the description are omitted for clarity, and the same or similar constituent elements are indicated by the same reference numeral throughout the specification.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Hereinafter, the terms “lower portion” or “under” and “upper portion” or “on” are for convenience of description and do not limit the positional relationship. Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below. “About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, when a definition is not otherwise provided, the energy level is the highest occupied molecular orbital (HOMO) energy level or the lowest unoccupied molecular orbital (LUMO) energy level.

Hereinafter, when a definition is not otherwise provided, the work function or energy level is expressed as an absolute value from the vacuum level. In addition, the work function or energy level is referred to be deep, high, or large, it may have a large absolute value based on zero electron volt “0 eV” of the vacuum level while when the work function work function or energy level is referred to be shallow, low, or small, it may have a small absolute value based on “0 eV” of the vacuum level. Further, the differences between the work function and/or the energy level may be values obtained by subtracting a small value of the absolute value from a large value of the absolute value.

Hereinafter, when a definition is not otherwise provided, the HOMO energy level may be evaluated with an amount of photoelectrons emitted by energy when irradiating UV light to a thin film using AC-2 (Hitachi) or AC-3 (Riken Keiki Co., Ltd.).

Hereinafter, when a definition is not otherwise provided, the LUMO energy level may be obtained by obtaining an energy bandgap using a UV-Vis spectrometer (Shimadzu Corporation), and then calculating the LUMO energy level from the energy bandgap and the already measured HOMO energy level.

Hereinafter, ‘metal’ includes a metal and a semi-metal.

Hereinafter, the description of not containing cadmium (or other toxic heavy metal) may refer to a concentration of cadmium (or the heavy metal) of less than or equal to about 100 ppm, less than or equal to about 50 ppm, less than or equal to about 10 ppm, or substantially zero. In an embodiment, it is not excluded that cadmium (or the corresponding heavy metal) may be substantially absent, or if present, in an amount below the detection limit of a given detection means or at an impurity level.

A quantum dot display panel 1000 according to an embodiment is described with reference to the drawings below.

A quantum dot display panel 1000 according to an embodiment may be a multi-functional display panel which may perform both a self-luminous display function and a user interaction function by stimulus detection by using quantum dots having luminescence characteristics and quantum dots having light-absorption characteristics.

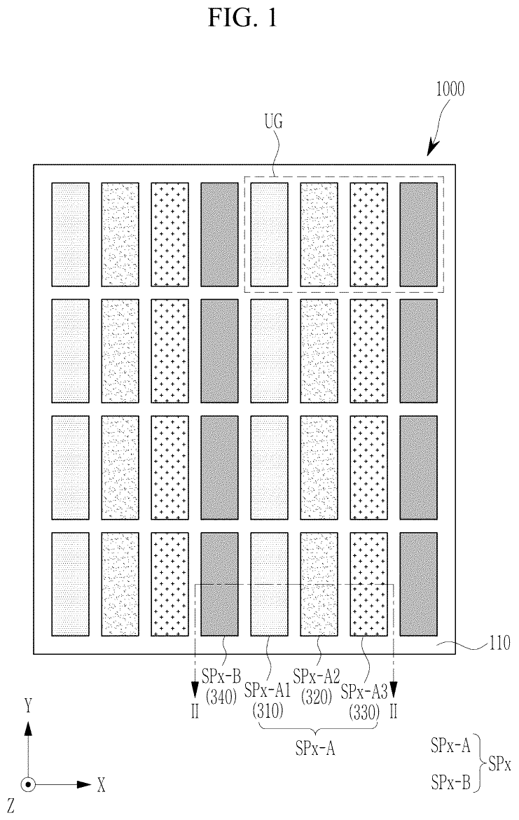

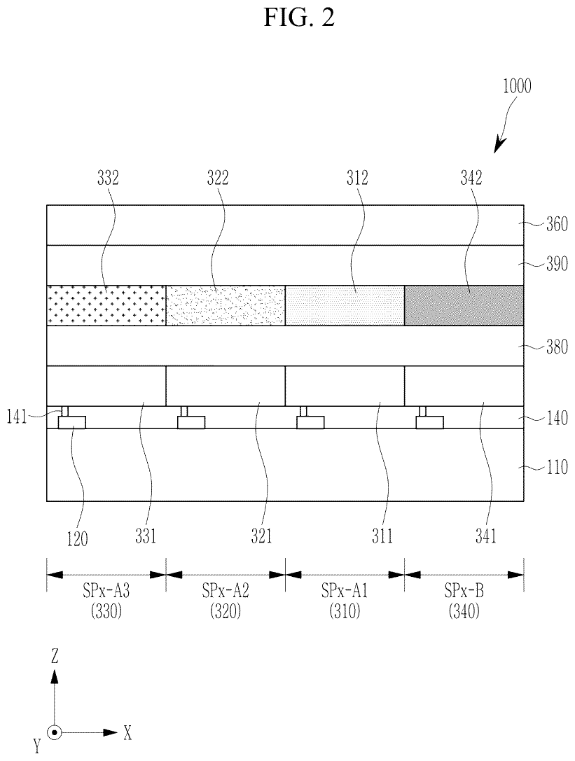

FIG. 1 is a plan view schematically showing an example of a quantum dot display panel 1000 according to an embodiment, and FIG. 2 is a cross-sectional view taken along line II-II of the quantum dot display panel of FIG. 1.

Referring to FIG. 1, a quantum dot display panel 1000 according to an embodiment includes a plurality of sub-pixels SPx, some of the plurality of sub-pixels SPx may be display sub-pixels SPx-A for displaying colors, and some of the plurality of sub-pixels SPx may be detection sub-pixels SPx-B. The display sub-pixels SPx-A and the detection sub-pixels SPx-B may be arranged side by side and may be arranged along rows and/or columns or randomly to form an array.

A display sub-pixel SPx-A may display at least three primary colors, and may include, for example, a first sub-pixel SPx-A1 displaying red, a second sub-pixel SPx-A2 displaying green, and a third sub-pixel SPx-A3 displaying blue. However, the present disclosure is not limited thereto, and may further include auxiliary sub-pixels (not shown), such as a white sub-pixel.

The detection sub-pixel (hereinafter referred to as the “fourth sub-pixel”) SPx-B may detect light of a predetermined wavelength, and for example, may absorb light in the visible to infrared wavelength region (or range) and photoelectrically convert the absorbed light to an electrical signal.

Referring to FIGS. 1 and 2, a quantum dot display panel 1000 according to an embodiment includes a substrate 110, a sub-pixel circuit portion 120, an insulating layer 140, and first, second, and third quantum dot light emitting diodes 310, 320, and 330 and a quantum dot sensor 340 arranged side by side along an in-plane direction (e.g., XY direction) of the substrate 110. The first quantum dot light emitting diode 310 may be included in a first sub-pixel SPx-A1, the second quantum dot light emitting diode 320 may be included in a second sub-pixel SPx-A2, the third quantum dot light emitting diode 330 may be included in a third sub-pixel SPx-A3, and the quantum dot sensor 340 may be included in a fourth sub-pixel SPx-B.

At least one first sub-pixel SPx-A1, at least one second sub-pixel SPx-A2, and at least one third sub-pixel SPx-A3 may form one unit group UG and may be repeatedly arranged along an in-plane direction (e.g., XY direction) of the substrate 110, and at least some of the repeatedly arranged unit groups UG may further include at least one fourth sub-pixel SPx-B.

The substrate 110 may be a semiconductor substrate such as a silicon substrate, a glass substrate, or a polymer substrate such as polycarbonate, polymethyl methacrylate, polyethylene terephthalate, polyethylene naphthalate, polyamide, polyether sulfone, or a combination thereof, but is not limited thereto.

The sub-pixel circuit portion 120 is positioned on the substrate 110 and is included in each of the first, second, third, and fourth sub-pixels SPx-A1, SPx-A2, SPx-A3, and SPx-B, so as to independently switch and/or drive the first, second, third, and fourth sub-pixels SPx-A1, SPx-A2, SPx-A3, and SPx-B. The sub-pixel circuit portion 120 may include one or more thin film transistors (TFTs), for example, at least one switching thin film transistor and/or at least one driving thin film transistor. The substrate 110 on which a sub-pixel circuit portion 120 including a thin film transistor is formed may be called a thin film transistor substrate (TFT substrate) or a thin film transistor backplane (TFT backplane).

The insulating layer 140 may cover the substrate 110 and the sub-pixel circuit portion 120 and may be formed on the entire surface of the substrate 110. The insulating layer 140 may be, for example, a planarizing layer, a passivation layer, and/or an encapsulating layer. The insulating layer 140 may include an organic insulating material, an inorganic insulating material, an organic-inorganic insulating material, or a combination thereof. The insulating layer 140 may include, for example, an inorganic insulating material such as silicon oxide, silicon nitride, silicon oxynitride, aluminum oxide, aluminum nitride, aluminum oxynitride, or a combination thereof, an organic insulating material such as polyimide, polyamide, polyamideimide, polyacrylate, or a combination thereof, an organic-inorganic insulating material such as polyorganosiloxane, polyorganosilazane, or a combination thereof, or a combination thereof. The insulating layer 140 may have a plurality of contact holes 141 defined therein for connecting the first, second, and third quantum dot light emitting diodes 310, 320, and 330 and the quantum dot sensor 340, to the sub-pixel circuit portion 120, respectively.

The first, second, and third quantum dot light emitting diodes 310, 320, and 330 and the quantum dot sensor 340 are disposed on the substrate 110 and arranged side by side along the in-plane direction (e.g., XY direction) of the substrate 110. The first, second, and third quantum dot light emitting diodes 310, 320, and 330 and the quantum dot sensor 340 are electrically connected to each sub-pixel circuit portion 120 included in each of the first, second, third, and fourth sub-pixels SPx-A1, SPx-A2, SPx-A3, and SPx-B through contact holes 141 of the insulating layer 140 and may be driven independently.

The first quantum dot light emitting diode 310 includes a pixel electrode 311, a first quantum dot layer 312, a common electrode 360, a first common auxiliary layer 380, and a second common auxiliary layer 390, on a substrate 110. The second quantum dot light emitting diode 320 includes a pixel electrode 321, a second quantum dot layer 322, a common electrode 360, a first common auxiliary layer 380, and a second common auxiliary layer 390, on a substrate 110. The third quantum dot light emitting diode 330 includes a pixel electrode 331, a third quantum dot layer 332, a common electrode 360, a first common auxiliary layer 380, and a second common auxiliary layer 390 on a substrate 110. The quantum dot sensor 340 includes a pixel electrode 341, a fourth quantum dot layer 342, a common electrode 360, a first common auxiliary layer 380, and a second common auxiliary layer 390.

The pixel electrodes 311, 321, 331, and 341 are separated for each of the sub-pixels SPx-A1, SPx-A2, SPx-A3, and SPx-B and are electrically connected to a corresponding sub-pixel circuit portion 120 of the first, second, third, and fourth sub-pixels SPx-A1, SPx-A2, SPx-A3, and SPx-B. The pixel electrodes 311, 321, 331, and 341 of a pixel electrode layer may be positioned below the first, second, third or fourth quantum dot layers 312, 322, 332, and 342 of a quantum dot layer, and may be arranged side by side along the in-plane direction (e.g., XY direction) of the substrate 110. The pixel electrodes 311, 321, 331, and 341 may be an anode or a cathode, for example, an anode.

The pixel electrodes 311, 321, 331, and 341 and/or the first, second, third or fourth quantum dot layers 312, 322, 332, and 342 may respectively be in a same layer, such as in the pixel electrode layer and the quantum dot layer. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

The pixel electrodes 311, 321, 331, and 341 may be a light-transmitting electrode or a reflective electrode, and may be, for example, a reflective electrode including a reflective layer.

For example, the pixel electrodes 311, 321, 331, and 341 may be formed of (or include) a reflective layer including an optically opaque material. The reflective layer may have a light transmittance of, for example, less than about 10 percent (%), for example, less than or equal to about 8%, less than or equal to about 7%, less than or equal to about 5%, less than or equal to about 3%, or less than or equal to about 1%. The reflective layer may have a reflectivity of, for example, greater than or equal to about 10%, and may have a reflectivity of, for example, greater than or equal to about 20%, greater than or equal to about 30%, greater than or equal to about 50%, or greater than or equal to about 70%. The optically opaque material may include a metal, a metal nitride, or a combination thereof, and may include, for example, silver (Ag), copper (Cu), aluminum (Al), gold (Au), titanium (Ti), chromium (Cr), nickel (Ni), an alloy thereof, a nitride thereof (e.g., TiN), or a combination thereof, but is not limited thereto. The reflective layer may have one or more layers.

For example, the pixel electrodes 311, 321, 331, and 341 may include a reflective layer including an optically opaque material and a light transmitting layer including an optically transparent material. The reflective layer is as described above. The light transmitting layer may have a high transmittance of greater than or equal to about 80%, greater than or equal to about 85%, greater than or equal to about 88%, or greater than or equal to about 90%, and may include an optically transparent conductor. The light transmitting layer may include, for example, at least one of an oxide conductor, a carbon conductor, and/or a metal thin film. The oxide conductor may include, for example, one or more selected from indium tin oxide (ITO), indium zinc oxide (IZO), zinc tin oxide (ZTO), aluminum tin oxide (ATO), and aluminum zinc oxide (AZO), the carbon conductor may be one or more selected from graphene and carbon nanobodies, and the metal thin film may be, for example, a metal thin film formed of a thin thickness of several nanometers to tens of nanometers, or a single layer or multiple layers of metal thin film formed of a thin thickness of several nanometers to several tens of nanometers, the metal thin film being doped with metal oxide.

For example, the pixel electrodes 311, 321, 331, and 341 may be formed of a reflective layer or may have a stacked structure of a reflective layer/light transmitting layer or a light transmitting layer/reflective layer/light transmitting layer.

The common electrode 360 may be disposed on the first, second, third, and fourth quantum dot layers 312, 322, 332, and 342 and may face the pixel electrodes 311, 321, 331, and 341 respectively, with the first, second, third or fourth quantum dot layers 312, 322, 332, and 342 interposed therebetween. The common electrode 360 may be a cathode or an anode, for example, a cathode.

Planar portions of the common electrode 360 may be connected to each other and formed continuously in the first, second, third, and fourth sub-pixels SPx-A1, SPx-A2, SPx-A3, and SPx-B. A common voltage may be applied to the first, second, and third quantum dot light emitting diodes 310, 320, and 330 and the quantum dot sensor 340. However, the present disclosure is not limited thereto and the common electrode 360 may be separated from each of the first, second, third and fourth sub-pixels SPx-A1, SPx-A2, SPx-A3, and SPx-B.

The common electrode 360 may be a light transmitting electrode or a reflecting electrode, for example, a light transmitting electrode. The light transmitting electrode may include, for example, a light transmitting layer, a semi-transmitting layer, or a combination thereof. The light transmitting layer is as described above. The semi-transmitting layer may have a light transmittance between the light transmitting layer and the reflective layer, and may have a light transmittance of about 10% to about 70%, about 20% to about 60%, or about 30% to about 50%. The semi-transmitting layer may selectively transmit light of a certain wavelength region and reflect and/or absorb light of other wavelength regions. The semi-transmitting layer may include a thin metal layer or alloy layer having a thickness of, for example, about 1 nanometer (nm) to about 50 nm, and may include, silver (Ag), copper (Cu), aluminum (Al), magnesium (Mg), magnesium-silver (Mg—Ag), magnesium-aluminum (Mg—Al), or a combination thereof, but is not limited thereto. For example, when the common electrode 360 is a light transmitting electrode and the pixel electrodes 311, 321, 331, and 341 are reflective electrodes, the quantum dot display panel 1000 may be a top emission type display panel which emits light toward the common electrode 360.

The first, second, and third quantum dot layers 312, 322, and 332 are disposed on the pixel electrodes 311, 321, and 331 and between the pixel electrodes 311, 321, and 331 and the common electrode 360. The fourth quantum dot layer 342 is disposed on the pixel electrode 341 and between the pixel electrode 341 and the common electrode 360. The first, second, third, and fourth quantum dot layers 312, 322, 332, and 342 may be arranged side by side along the in-plane direction (e.g., XY direction) of the substrate 110.

The first, second, and third quantum dot layers 312, 322, and 332 may emit light in different wavelength regions within the visible light region, and for example, the first quantum dot layer 312 may emit light in a red wavelength region (or range), the second quantum dot layer 322 may emit light in a green wavelength region, and the third quantum dot layer 332 may emit light in a blue wavelength region. Red light may have for example a peak emission wavelength (λ_{peak,L}) in the range of greater than about 600 nanometers (nm) and less than or equal to about 680 nm, green light may have for example a peak emission wavelength (λ_{peak,L}) in the range of about 510 nm to about 580 nm, and blue light may have for example a peak emission wavelength (λ_{peak,L}) in the range of about 430 nm to about 480 nm.

The emission spectra of the first, second, and third quantum dot layers 312, 322, and 332 may have a relatively narrow full width at half maximum (FWHM). Here, the FWHM may be a width of the wavelength corresponding to half of the maximum emission point (peak emission point) in the emission spectrum. The FWHM of the emission spectrum of the first, second, and third quantum dot layers 312, 322, and 332 may be, for example, less than or equal to about 60 nm, within the above range, for example, less than or equal to about 55 nm, less than or equal to about 52 nm, less than or equal to about 50 nm, less than or equal to about 49 nm, less than or equal to about 48 nm, less than or equal to about 47 nm, less than or equal to about 46 nm, less than or equal to about 45 nm, less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, less than or equal to about 35 nm, less than or equal to about 34 nm, less than or equal to about 33 nm, less than or equal to about 32 nm, less than or equal to about 31 nm, less than or equal to about 30 nm, less than or equal to about 29 nm, or less than or equal to about 28 nm, for example, about 2 nm to about 60 nm, about 2 nm to about 55 nm, about 2 nm to about 50 nm, about 2 nm to about 49 nm, about 2 nm to about 48 nm, about 2 nm to about 47 nm, about 2 nm to about 46 nm, about 2 nm to a 45 nm, about 2 nm to about 44 nm, about 2 nm to about 43 nm, about 2 nm to about 42 nm, about 2 nm to about 41 nm, about 2 nm to about 40 nm, about 2 nm to about 39 nm, about 2 nm to about 38 nm, about 2 nm to about 37 nm, about 2 nm to about 36 nm, about 2 nm to about 35 nm, about 2 nm to about 34 nm, about 2 nm to about 33 nm, about 2 nm to about 32 nm, about 2 nm to about 31 nm, about 2 nm to about 30 nm, about 2 nm to about 29 nm, or about 2 nm to about 28 nm. The first, second, and third quantum dot layers 312, 322, and 332 having a relatively narrow FWHM emission spectrum may exhibit high color purity within the corresponding wavelength region, thereby enabling high-quality color expression.

The fourth quantum dot layer 342 may absorb at least a portion of light in the visible to infrared wavelength region, for example, may absorb at least a portion of light in the blue wavelength region, the green wavelength region, the red wavelength region, and the infrared wavelength region. Herein, the infrared wavelength region may include near-infrared, mid-infrared, and far-infrared. For example, the fourth quantum dot layer 342 may absorb light in the visible light from blue to red wavelength region. For example, the fourth quantum dot layer 342 may absorb at least a portion of the light from red to near-infrared wavelength region. The fourth quantum dot layer 342 may absorb light in the above wavelength region and convert the absorbed light into an electrical signal.

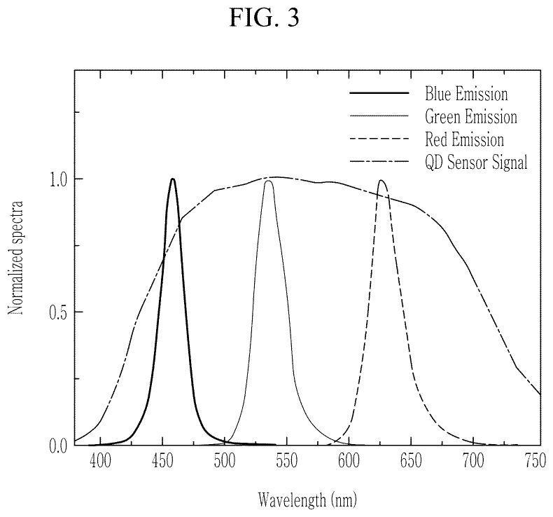

FIG. 3 is an optical spectrum showing an example of the luminescence and light-absorption characteristics of the first, second, and third quantum dot light emitting diodes and the quantum dot sensor in the quantum dot display panels of FIGS. 1 and 2.

Referring to FIG. 3, the first, second, and third quantum dot light emitting diodes 310, 320, and 330 (the first, second, and third sub-pixels SPx-A1, SPx-A2, and SPx-A3) may emit light in red, green and blue wavelength regions with relatively narrow FWHMs, respectively, and the quantum dot sensor 340 may absorb light in at least a portion of a visible to infrared wavelength region, and for example, a wavelength region absorbed by the quantum dot sensor 340 may at least partially overlap with a wavelength region of light emitted from the first, second, and third quantum dot light emitting diodes 310, 320, and 330.

The first, second, third, and fourth quantum dot layers 312, 322, 332, and 342 each include quantum dots. The quantum dots may be a semiconductor nanocrystal in a general concept, and may have various shapes, for example an isotropic semiconductor nanocrystal, a quantum rod, and a quantum plate. Here, the quantum rod may mean a quantum dot having an aspect ratio greater than about 1, for example, an aspect ratio of greater than or equal to about 2, greater than or equal to about 3, or greater than or equal to about 5. For example, an aspect ratio of the quantum rod may be less than or equal to about 50, less than or equal to about 30, or less than or equal to about 20.

The quantum dots may have, for example a particle diameter (an average largest particle diameter for a non-spherical shape) of about 1 nm to about 100 nm, for example about 1 nm to about 80 nm, for example about 1 nm to about 50 nm, for example about 1 nm to about 20 nm.

The quantum dots have a tunable energy band gap depending on their configuration, size, and/or composition, and thus their emission wavelength or absorption wavelength (detection wavelength). For example, the larger the size of the quantum dots, the narrower the energy band gap they may have, and thus may emit or absorb (detect) light in a relatively long wavelength region, and the smaller the size of the quantum dots, the wider the energy band gap they may have, and thus may emit or absorb (detect) light in a relatively short wavelength region.

For example, by precisely controlling the size and composition of quantum dots and reducing surface defects, a narrow FWHM emission spectrum may be realized, thereby providing good color purity and optical characteristics, and expanding the color expression range of the display panel and realizing color implementation and color reproducibility close to reality.

For example, by precisely controlling the size and composition of quantum dots, they may be tuned to have high absorption coefficients over a broad absorption band while also having selectively high absorption properties at a given wavelength.

The first, second, and third quantum dot layers 312, 322, and 332 may include light-emitting quantum dots which emit light in a predetermined wavelength region, and the fourth quantum dot layer 342 may include light-absorbing quantum dots which absorb light in a predetermined wavelength region.

For example, the light-emitting quantum dots and the light-absorbing quantum dots may each independently include a Group II-VI semiconductor compound, a Group III-V semiconductor compound, a Group IV-VI semiconductor compound, a Group IV semiconductor, a Group I-III-VI semiconductor compound, a Group I-II-IV-VI semiconductor compound, a Group II-III-V semiconductor compound, or a combination thereof.

The Group II-VI semiconductor compound may be for example selected from a binary element compound selected from CdSe, CdTe, ZnS, ZnSe, ZnTe, ZnO, HgS, HgSe, HgTe, MgSe, MgS, and a combination thereof, a ternary element compound selected from CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a combination thereof, and a quaternary element compound selected from HgZnTeS, CdZnSeS, CdZnSeTe, CdZnSTe, CdHgSeS, CdHgSeTe, CdHgSTe, HgZnSeS, HgZnSeTe, HgZnSTe, and a combination thereof, but is not limited thereto. The Group III-V semiconductor compound may be for example selected from a binary element compound selected from GaN, GaP, GaAs, GaSb, AlN, AIP, AlAs, AISb, InN, InP, InAs, InSb, and a combination thereof, a ternary element compound selected from GaNP, GaNAs, GaNSb, GaPAs, GaPSb, AlNP, AlNAs, AlNSb, AlPAs, AIPSb, InNP, InNAs, InNSb, InPAs, InPSb, GaAlNP, and a combination thereof, and a quaternary element compound selected from GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a combination thereof, but is not limited thereto. The Group IV-VI semiconductor compound may be for example selected from a binary element compound selected from SnS, SnSe, SnTe, PbS, PbSe, PbTe, and a combination thereof, a ternary element compound selected from SnSeS, SnSeTe, SnSTe, PbSeS, PbSeTe, PbSTe, SnPbS, SnPbSe, SnPbTe, and a combination thereof, and a quaternary element compound selected from SnPbSSe, SnPbSeTe, SnPbSTe, and a combination thereof, but is not limited thereto. The Group IV semiconductor may be for example selected from a singular element semiconductor selected from Si, Ge, and a combination thereof, and a binary element semiconductor compound selected from SiC, SiGe, and a combination thereof, but is not limited thereto. The Group I-III-VI semiconductor compound may be for example selected from a ternary element compound selected from AgInS, AgInS₂, AgInSe₂, AgGaS, AgGaS₂, AgGaSe₂, CulnS, CuInS₂, CuInSe₂, CuGaS₂, CuGaSe₂, CuGaO₂, AgGaO₂, and AgAIO₂, a quaternary element compound selected from AgInGaS₂, AgInGaSe₂, CuInGaSe, and CuInGaS, or any combination thereof, but is not limited thereto. The Group I-II-IV-VI semiconductor compound may be for example selected from CuZnSnSe, CuZnSnS, or any combination thereof, but is not limited thereto. The Group II-III-V semiconductor compound may include for example InZnP, but is not limited thereto.

The quantum dot may include the singular element semiconductor, the binary element semiconductor compound, the ternary element semiconductor compound, or the quaternary element semiconductor compound in a substantially uniform concentration or partially different concentration distributions. Each element included in a multi-element compound such as the binary element semiconductor compound, the ternary element semiconductor compound, and the quaternary element semiconductor compound may be present at a uniform or nonuniform concentration in a particle. In other words, a chemical formula representing the compound indicates a type of elements included in the compound but does not limit an element ratio of each element. All the elements included in each compound may have a different element ratio, for example, AgInGaS₂ may mean AgInₓGa₁₋ₓS₂ (0≤x≤1).

For example, the light-absorbing quantum dots may be semiconductor compounds including cadmium (Cd) and/or lead (Pb) and a chalcogen element. For example, the light-absorbing quantum dots may be a CdS semiconductor compound, a CdSe semiconductor compound, and/or a PbS semiconductor compound.

For example, the light-absorbing quantum dot may be a non-cadmium quantum dot, and may be a semiconductor compound including two, three or four selected from indium (In), gallium (Ga), arsenic (As), and antimony (Sb). For example, the quantum dots may be an In—As semiconductor compound, an In—Ga—As semiconductor compound, an In—Sb semiconductor compound, and/or a Ga—As semiconductor compound.

For example, the light-emitting quantum dots may be a non-cadmium quantum dot, and may be a semiconductor compound including at least one of zinc (Zn), tellurium (Te), and selenium (Se). For example, the light-emitting quantum dots may be a Zn—Te semiconductor compound, a Zn—Se semiconductor compound, and/or a Zn—Se—Te semiconductor compound. For example, in a Zn—Se—Te semiconductor compound, a mole fraction of tellurium (Te) may be less than a mole fraction of selenium (Se).

For example, the light-emitting quantum dot may be a semiconductor compound including indium (In) and at least one of zinc (Zn) and phosphorus (P). For example, the quantum dot may be an In—P semiconductor compound and/or an In—Zn—P semiconductor compound. For example, in the In—Zn—P semiconductor compound, a mole ratio of zinc (Zn) to indium (In) may be greater than or equal to about 25.

The quantum dot may have a core-shell structure where one quantum dot surrounds another quantum dot. For example, the core and the shell of the quantum dot may have an interface, and an element of at least one of the core or the shell in the interface may have a concentration gradient where the concentration of the element(s) of the shell decreases toward the core. For example, a material composition of the shell of the quantum dot has a higher energy bandgap than a material composition of the core of the quantum dot, and thereby the quantum dot may exhibit a quantum confinement effect.

The quantum dot may have one quantum dot core and a multi-layered quantum dot shell surrounding the core. Herein, the multi-layered shell has at least two shells where each shell may be a single composition, an alloy, and/or a concentration gradient For example, a shell of a multi-layered shell which is far from the core may have a higher energy bandgap than a shell which is near to the core, and thereby the quantum dot may exhibit a quantum confinement effect.

Quantum dots have a very low exciton binding energy compared to organic semiconductors, so that the generated excitons are relatively easily separated into electron-hole pairs and have high charge separation efficiency, and thus they may be used as a photovoltaic material alone without a separate counterpart material. However, this does not exclude the inclusion of additional counterpart materials. For example, a quantum dot layer formed by a p-n homojunction from quantum dots having relatively p-type characteristics (e.g., p-type InAs quantum dots, Zn-doped p-type InAs quantum dots) and quantum dots having relatively n-type characteristics (e.g., n-type InAs quantum dots) may be included, thereby increasing the depletion length and thus the photoelectric conversion efficiency, reducing the dark current, and ultimately enhancing the sensitivity of the sensor.

Each thickness of the first, second, third, and fourth quantum dot layers 312, 322, 332, and 342 may be less than or equal to about 200 nm, for example about 5 nm to about 200 nm, about 10 nm to about 200 nm, about 20 nm to about 150 nm, about 20 nm to about 100 nm, about 30 nm to about 100 nm, about 20 nm to about 80 nm, or about 30 nm to about 80 nm.

A pixel definition layer (not shown) may be formed between the first, second, third, and fourth quantum dot layers 312, 322, 332, and 342. The pixel definition layer may separate the first, second, third, and fourth quantum dot layers 312, 322, 332, and 342 from each other.

The first common auxiliary layer 380 may be disposed between the pixel electrodes 311, 321, 331, and 341, and the first, second, third, and fourth quantum dot layers 312, 322, 332, and 342, respectively. Portions of the first common auxiliary layer 380 may be connected to each other and formed continuously in each sub-pixel SPx-A1, SPx-A2, SPx-A3, and SPx-B.

The first common auxiliary layer 380 may be disposed between the pixel electrodes 311, 321, 331, and 341, and the first, second, third, and fourth quantum dot layers 312, 322, 332, and 342, respectively, to improve electrical performance, and may include one or two or more layers. For example, when the pixel electrodes 311, 321, 331, and 341 is an anode, the first common auxiliary layer 380 may include a hole injection layer, a hole transport layer, a hole extraction layer, an electron blocking layer, or a combination thereof.

The HOMO energy level of the first common auxiliary layer 380 may be equal to or less than the HOMO energy levels of the first, second, third, and fourth quantum dot layers 312, 322, 332, and 342 by about 1.0 eV. For example, a difference between the HOMO energy levels of the first common auxiliary layer 380 and the first, second, third, and fourth quantum dot layers 312, 322, 332, and 342 may be about 0 eV to about 1.0 eV, and within the range, for example, about 0.01 eV to about 0.8 eV, for example, about 0.01 eV to about 0.7 eV, for example, about 0.01 eV to about 0.5 eV, for example, about 0.01 eV to about 0.4 eV, for example, about 0.01 eV to about 0.3 eV, for example, about 0.01 eV to about 0.2 eV, for example, about 0.01 eV to about 0.1 eV.

The HOMO energy level of the first common auxiliary layer 380 may be, for example, greater than or equal to about 5.0 eV, within the range, for example, greater than or equal to about 5.1 eV, for example, greater than or equal to about 5.2 eV, for example, greater than or equal to about 5.3 eV, for example, greater than or equal to about 5.4 eV.

For example, the HOMO energy level of the first common auxiliary layer 380 may be about 5.0 eV to about 7.0 eV, and within the range, for example, about 5.1 eV to about 6.8 eV, for example, about 5.2 eV to about 6.8 eV, for example, about 5.3 eV to about 6.7 eV, for example, about 5.3 eV to about 6.5 eV, for example, about 5.4 eV to about 6.3 eV, for example, about 5.4 eV to about 6.2 eV, for example, about 5.4 eV to about 6.1 eV.

For example, the first common auxiliary layer 380 may include an organic material, an inorganic material, an organic-inorganic material, or a combination thereof and may include, for example, N,N,N′,N′-tetrakis(4-methoxyphenyl)-benzidine (TPD), N,N′-bis(1-naphthyl)-N,N′-diphenyl-(1,1′-biphenyl)-4,4′-diamine (NPD), 4,4′,4″-tris[phenyl(m-tolyl)amino]triphenylamine) (m-MTDATA), 4,4′,4″-tris(N-carbazolyl)-triphenylamine, TCTA), 1,1-bis[(di-4-tolylamino)phenyl]cyclohexane (TAPC), N2,N7-di(naphthalen-1-yl)-9,9-dioctyl-N2,N7-diphenyl-9H-fluorene-2,7-diamine (NPB), 2,7-bis(carbazol-9-yl)-9,9-spirobifluorene (Spiro-2CBP), 2,2′,7,7′-Tetra(N,N-di-p-tolyl)amino-9,9-spirobifluorene (Spiro-TTB), 2,2′,7,7′-tetrakis(N,N-diphenylamino)-9,9-spirobifluorene (Spiro-TAD), 1,1-bis[(di-4-tolylamino)phenyl]cyclohexane (TAPC), 4,4′-Bis(N-carbazolyl)-1,1′-biphenyl (CBP), 4,4′,4″-tris[2-naphthyl(phenyl)amino]triphenylamine (2-TNATA), 1,3,5-tris (4-diphenylaminophenyl)benzene (TDAPB), poly(9,9-dioctyl-fluorene-co-N-(4-butylphenyl)-diphenylamine) (TFB), polyarylamine, poly(N-vinylcarbazole), poly (3,4-ethylenedioxythiophene(poly (3,4-ethylenedioxythiophene), PEDOT), poly (3,4-ethylenedioxythiophene)polystyrene sulfonate (PEDOT:PSS), polyaniline, polypyrrole, Spiro-PMATD, triphenylbismuth dichloride (TPBC), poly(triaryl amine) (PTAA), poly(3-hexylthiophene-2,5-diyl) (P3HT), poly[3-(5-carboxypentyl)thiophene-2,5-diyl](P3CPenT), poly[2,6-(4,4-bis-(2-ethylhexyl)-4H-cyclopenta[2,1-b,3,4-b′]dithiophene)-alt-4,7(2,1,3-benzothiadiazole)](PCPDT-t), poly(2,3-dihydrothieno[3,4-b][1,4]dioxane-5,7-diyl) (PEDOT-S), poly ferric sulfate (PFS), CuI, Cu₂O, CuO, CuS, NiOx, CuGaO₂, CuPc, CuSCN, MoOₓ, MoS₂, VOₓ, CoOₓ, graphene oxide, or a combination thereof, but is not limited thereto.

The second common auxiliary layer 390 may be disposed between the common electrode 360 and the first, second, third, and fourth quantum dot layers 312, 322, 332, and 342. Portions of the second common auxiliary layer 390 may be connected to each other and formed continuously in each sub-pixel SPx-A1, SPx-A2, SPx-A3, and SPx-B.

The second common auxiliary layer 390 may be disposed between the common electrode 360, and the first, second, third, and fourth quantum dot layers 312, 322, 332, and 342, to improve electrical performance, and may include one or two or more layers. For example, when the common electrode 360 is a cathode, the second common auxiliary layer 390 may include an electron injection layer, an electron transport layer, an electron extraction layer, a hole blocking layer, or a combination thereof. The second common auxiliary layer 390 may include, for example, an organic material, an inorganic material, an organic-inorganic material, or a combination thereof.

The LUMO energy level of the second common auxiliary layer 390 may be, for example, equal to the LUMO energy levels of the first, second, third, and fourth quantum dot layers 312, 322, 332, and 342 or the work function of the common electrode 360, or may be between the LUMO energy levels of the first, second, third, and fourth quantum dot layers 312, 322, 332, and 342 and the work function of the common electrode 360. For example, the work function of the common electrode 360, the LUMO energy level of the second common auxiliary layer 390, and the LUMO energy levels of the first, second, third, and fourth quantum dot layers 312, 322, 332, and 342 may become increasingly shallower, for example, step-like.

The HOMO energy level of the second common auxiliary layer 390 may be deeper than, for example, the HOMO energy levels of the first, second, third, and fourth quantum dot layers 312, 322, 332, and 342. For example, the HOMO energy level of the second common auxiliary layer 390 may be deeper than the HOMO energy levels of the first, second, third, and fourth quantum dot layers 312, 322, 332, and 342 by greater than or equal to about 0.2 eV, greater than or equal to about 0.5 eV, greater than or equal to about 0.8 eV, greater than or equal to about 1.0 eV, greater than or equal to about 1.2 eV, or greater than or equal to about 1.5 eV, for example, about 0.2 eV to about 4.0 eV, about 0.5 eV to about 4.0 eV, about 0.8 eV to about 4.0 eV, about 1.0 eV to about 4.0 eV, about 1.2 eV to about 4.0 eV, or about 1.5 eV to about 4.0 eV.

For example, the second common auxiliary layer 390 may have a relatively deep HOMO energy level, and the HOMO energy level of the second common auxiliary layer 390 may be, for example, about 5.6 eV to about 8.5 eV, within the above range, about 5.8 eV to about 8.2 eV, about 6.0 eV to about 8.0 eV, about 6.2 eV to about 8.0 eV, about 6.5 eV to about 8.0 eV, about 6.8 eV to about 8.0 eV, about 7.0 eV to about 8.0 eV, about 7.2 eV to about 7.9 eV, or about 7.3 eV to about 7.8 eV. The second common auxiliary layer 390 has such energy levels that it may effectively transmit electrons and effectively block holes in each sub-pixel SPx-A1, SPx-A2, SPx-A3, and SPx-B, thereby simultaneously improving the electrical properties of the first, second, and third quantum dot light emitting diodes 310, 320, and 330 and the quantum dot sensor 340.

For example, the second common auxiliary layer 390 may include inorganic nanoparticles. The inorganic nanoparticles may be, for example, oxide nanoparticles, for example, metal oxide nanoparticles, or for example, metal oxide nanoparticles including two or more types of metals. The inorganic nanoparticles may be two-dimensional or three-dimensional nanoparticles having an average particle size of several nanometers, for example, less than about 10 nm, less than or equal to about 9 nm, less than or equal to about 8 nm, less than or equal to about 7 nm, less than or equal to about 5 nm, less than or equal to about 4 nm, or less than or equal to about 3.5 nm, and within the above ranges, may have an average particle size of about 1 nm to about 10 nm, about 1 nm to about 9 nm, about 1 nm to about 8 nm, about 1 nm to about 7 nm, about 1 nm to about 5 nm, about 1 nm to about 4 nm, or about 1 nm to about 3.5 nm.

For example, the inorganic nanoparticles may be alkaline earth metal-containing oxide nanoparticles. The alkaline earth metal may be selected from, for example, beryllium (Be), magnesium (Mg), calcium (Ca), barium (Ba), strontium (Sr), radium (Ra) or a combination thereof, and may include, for example, magnesium (Mg). The alkaline earth metal-containing oxide nanoparticles may further include one or more metals in addition to the alkaline earth metal, and may further include, for example, at least one selected from zinc (Zn), cobalt (Co), nickel (Ni), gallium (Ga), zirconium (Zr), tungsten (W), titanium (Ti), tantalum (Ta), tin (Sn), and hafnium (Hf).

For example, the alkaline earth metal-containing oxide nanoparticles may include an alkaline earth metal and zinc (Zn). A content of the alkaline earth metal in the alkaline earth metal-containing oxide nanoparticles may be less than that of zinc (Zn), for example, the alkaline earth metal may be included in an amount of about 0.01 to about 30 at % or about 0.01 to about 20 at % based on the total number of metal atoms included in the alkaline earth metal-containing oxide nanoparticles, that is, the total number of alkaline earth metal and zinc.

As an example, inorganic nanoparticles may be represented by Zn₁₋ₓQₓO (Q is Be, Mg, Ca, Ba, Sr, Re, or a combination thereof, and 0<x<0.5). For example, Q may include Mg, and for example, 0.01≤x≤0.3 or 0.01≤x≤0.2.

The second common auxiliary layer 390 may further include an additive in addition to inorganic nanoparticles. The additive may be included in the form of a mixture with inorganic nanoparticles and may be included in a small amount to improve the electrical properties of the second common auxiliary layer 390.

The additive may be selected from, for example, an alkaline metal, an alkaline metal compound, an alkaline metal salt, or a combination thereof. The alkali metal may include, for example, lithium (Li), sodium (Na), potassium (K), cesium (Cs), rubidium (Rb), francium (Fr), or a combination thereof, the alkali metal compound may be a compound including the alkali metal, and the alkali metal salt may be a metal cation derived from the alkali metal compound. The additive may be, for example, an alkali metal compound and/or an alkali metal salt derived therefrom, where the additive may further include an anion such as carbonate (CO₃²⁻), phosphate (PO₄³⁻), vanadate (VO₄³⁻), azide (N₃⁻), or nitride (N³⁻).

For example, the additive may include lithium (Li), sodium (Na), potassium (K), cesium (Cs), rubidium (Rb), francium (Fr), cesium carbonate (Cs₂CO₃), cesium phosphate (Cs₃PO₄), cesium vanadate (Cs₃VO₄), cesium azide (CsN₃), lithium carbonate (LiCO₃), lithium nitride (Li₃N), sodium carbonate (Na₂CO₃), potassium carbonate (K₂CO₃), rubidium carbonate (Rb₂CO₃), or a combination thereof, but is not limited thereto.

The additive may be included in amounts less than inorganic nanoparticles. For example, the additive may be included in an amount of about 0.1 volume percent (volume %) to about 30 volume % based on the total content of the mixture of inorganic nanoparticles and additive. Within this range may be included in an amount of about 0.1 to about 25 vol %, about 0.1 to about 20 vol %, about 0.5 to about 18 vol %, about 1 to about 15 vol %, or about 3 to about 15 vol %.

A thickness of the first and second common auxiliary layers 380 and 390 may be, for example, greater than or equal to about 5 nm and less than about 80 nm, and within the above range, may be, for example, about 5 nm to about 70 nm, about 5 nm to about 60 nm, or about 5 nm to about 50 nm.

Meanwhile, when one of the pixel electrodes 311, 321, 331, and 341 and the common electrode 360 is a reflective electrode and the other is a transflective electrode (for example, when the pixel electrodes 311, 321, 331, and 341 are reflective electrodes and the common electrode 360 is a transflective electrode), the first, second, and third quantum dot light emitting diodes 310, 320, and 330 and/or the quantum dot sensor 340 may form a microcavity structure.

For example, light of a predetermined wavelength region among light emitted from the first, second, and/or third quantum dot layers 312, 322, and 332 of the first, second, and/or third quantum dot light emitting diodes 310, 320, and 330 may be repeatedly reflected between the pixel electrodes 311, 321, and 331 and the common electrode 360 and modified, and light of a wavelength region corresponding to a resonance wavelength of a micro-resonance among the modified light may be strengthened to exhibit amplified luminescence characteristics in a narrow wavelength region. Accordingly, the quantum dot display panel 1000 may exhibit colors with high color purity.

Since quantum dots have isotropic luminescence characteristics, unlike light emitting materials such as organic light emitting materials, light extraction efficiency in one direction (e.g., toward the common electrode 360) may be low, and accordingly, the microcavity structure in the first, second, and/or third quantum dot light emitting diodes 310, 320, and 330 may be different from the microcavity structure in the organic light emitting devices.

Specifically, light emitted from the first, second, and/or third quantum dot layers 312, 322, and 332 may be radiated in all directions due to the isotropic luminescence characteristics of the quantum dots, and accordingly, a portion of the light emitted from the first, second, and/or third quantum dot layers 312, 322, and 332 may move toward the pixel electrodes 311, 321, and 331 and be reflected by the reflective layer of the pixel electrodes 311, 321, and 331, and a portion of the light emitted from the first, second, and/or third quantum dot layers 312, 322, and 332 may move toward the common electrode 360 and be reflected by the common electrode 360, and such reflected lights may be amplified and modified into light of a predetermined wavelength range by repeatedly resonating between the pixel electrodes 311, 321, and 331 and the common electrode 360, and the modified light may be emitted to the outside, for example, by passing through the common electrode 360. That is, the modified light emitted through the common electrode 360 from the first, second, and/or third quantum dot layers 312, 322, and 332 may be different from the light emitted from the first, second, and/or third quantum dot layers 312, 322, and 332.

The resonance wavelength of the microcavity structure of the first, second, and/or third quantum dot light emitting diodes 310, 320, and 330 may be controlled to fall within the same region as the emission spectrum of the first, second, and/or third quantum dot layers 312, 322, and 332. When the first quantum dot layer 312 emits light in a red wavelength region, the first quantum dot light emitting diode 310 may be set to have a resonance wavelength within a red wavelength region, when the second quantum dot layer 322 emits light in a green wavelength region, the second quantum dot light emitting diode 320 may be set to have a resonance wavelength within a green wavelength region, and when the third quantum dot layer 332 emits light in a blue wavelength region, the third quantum dot light emitting diode 330 may be set to have a resonance wavelength within a blue wavelength region. The resonance wavelength may be one or more wavelengths.

Similarly, light of a predetermined wavelength region among light incident on the quantum dot sensor 340 may be modified by being repeatedly reflected between the pixel electrode 341 and the common electrode 360, and light of a wavelength region corresponding to the resonance wavelength of the microcavity among the modified light may exhibit enhanced and amplified photoelectric conversion characteristics (e.g., external quantum efficiency (EQE)). Accordingly, the quantum dot sensor 340 may exhibit high photoelectric conversion characteristics.

The method of manufacturing the quantum dot display panel 1000 may include forming (or providing) pixel electrodes 311, 321, 331, and 341 of a pixel electrode (or first electrode) layer on a substrate 110, forming a first common auxiliary layer 380 on the pixel electrode layer, forming first, second, third, and fourth quantum dot layers 312, 322, 332, and 342 of a quantum dot layer on the first common auxiliary layer 380, forming a second common auxiliary layer 390 on the quantum dot layer, and forming a common electrode 360 on the second common auxiliary layer 390.

The forming of the first common auxiliary layer 380, the forming of the first, second, third, and fourth quantum dot layers 312, 322, 332, and 342, and the forming of the second common auxiliary layer 390 may each be formed by a solution process, and may include spin coating, slit coating, inkjet printing, nozzle printing, spraying, and/or doctor blade coating, but are not limited thereto. The forming of the first common auxiliary layer 380 and the forming of the second common auxiliary layer 390 may be formed as a single layer on the entire surface of the substrate 110, and the forming of the first, second, third, and fourth quantum dot layers 312, 322, 332, and 342 may be performed, for example, by forming a pixel definition layer (not shown) between each sub-pixel SPx-A1, SPx-A2, SPx-A3, and SPx-B and using a common solution process for each sub-pixel SPx-A1, SPx-A2, SPx-A3, and SPx-B.

At least a portion of the forming of the first common auxiliary layer 380, the forming of the first, second, third, and fourth quantum dot layers 312, 322, 332, and 342, and the forming of a second common auxiliary layer 390 may further include optionally drying and/or heat treatment after the solution process, and the heat treatment may be performed, for example, at about 50 to about 300° C. for about 1 minute to about 10 hours, but are not limited thereto.

The quantum dot sensor 340 may be an optical recognition sensor which absorbs light and converts the absorbed light into an electrical signal. The quantum dot sensor may include an imaging sensor for obtaining a desired image from a living body such as a fingerprint, blood vessel distribution or blood vessel image, a signal detection sensor for obtaining desired information such as a biometric signal of the living body, a distance sensor for detecting a distance to an external object, and/or a motion sensor for detecting movement of an external object, or a combination thereof, but is not limited thereto. Herein, the living body may be a finger, a fingerprint, a palm, an iris, a face, and/or a wrist of a living body. The biometric signal may be blood pressure, pulse, and/or heart rate of the living body, but they are not limited thereto.

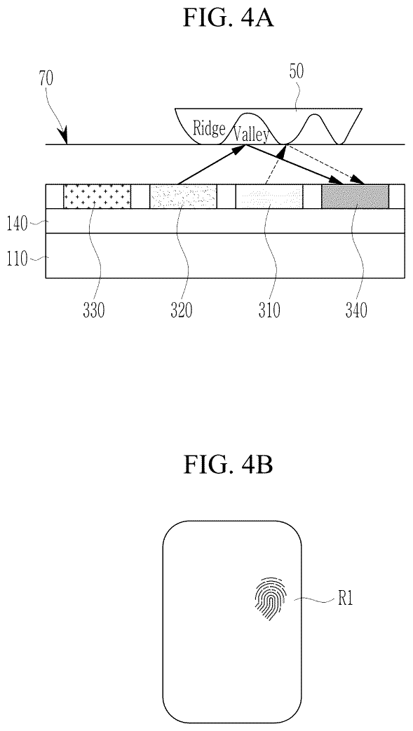

FIGS. 4A and 4B are schematic views showing an example of a fingerprint sensor using the quantum dot display panel 100 of FIGS. 1 and 2.

Referring to FIGS. 4A and 4B, when a finger of a living body is brought into contact with the quantum dot display panel 1000 (including the upper substrate 70 forming an outer surface of the quantum dot display panel 100), the fingerprint 50 may have a height difference between the ridge, which is a protruding portion, and the valley, which is a concave portion adjacent to the ridge, and the light reflected from the fingerprint 50 may be distinguished by this height difference. At least one of the first, second, and third quantum dot light emitting diodes 310, 320, and 330 may be used as a light source for light which is reflected by the finger, and one, two or three of the first, second, and/or third quantum dot light emitting diodes 310, 320, and 330 may be selected and used depending on the intended use. For example, when the first quantum dot light emitting diode 310 which emits light in a red wavelength region and/or the second quantum dot light emitting diode 320 which emits light in a green wavelength region are used, light emitted from the first quantum dot light emitting diode 310 may be reflected by the ridge of the fingerprint 50 and detected by the quantum dot sensor 340, and light emitted from the second quantum dot light emitting diode 320 may not reach the valley due to the height difference between the ridge and the valley, but may be reflected as is and detected by the quantum dot sensor 340. The information on the ridges and valleys detected by the quantum dot sensor 340 may be converted into electrical signals to obtain an image of the fingerprint 50.

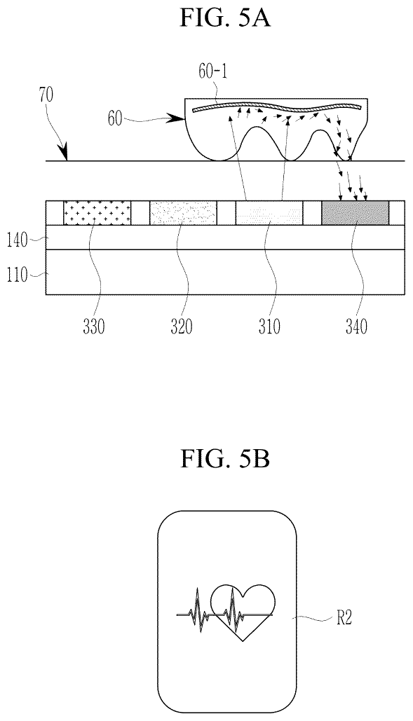

FIGS. 5A and 5B are schematic views showing an example of a biometric signal detection sensor using the quantum dot display panel 1000 of FIGS. 1 and 2.

Referring to FIGS. 5A and 5B, when a living body (e.g., wrist or chest) 60 is placed on the quantum dot display panel 1000 (including the upper substrate 70) and red light is irradiated from the first quantum dot light emitting diode 310, light reflected by a blood vessel 60-1 is detected by a quantum dot sensor 340 and converted into an electrical signal, thereby obtaining a biometric signal. However, the present disclosure is not limited thereto, and one, two, or three of the first, second, and/or third quantum dot light emitting diodes 310, 320, and 330 may be selected and used as a light source depending on the intended use.

As shown in FIGS. 4B and 5B, the image R1 and R2 may represent a relative location of the fingerprint 50 or the part of the living body across the in-plane direction (e.g., XY direction) of the upper substrate 70, a visual representation of the the fingerprint 50 or the part of the living body as a display of the quantum dot display panel 1000, etc. without being limited thereto.

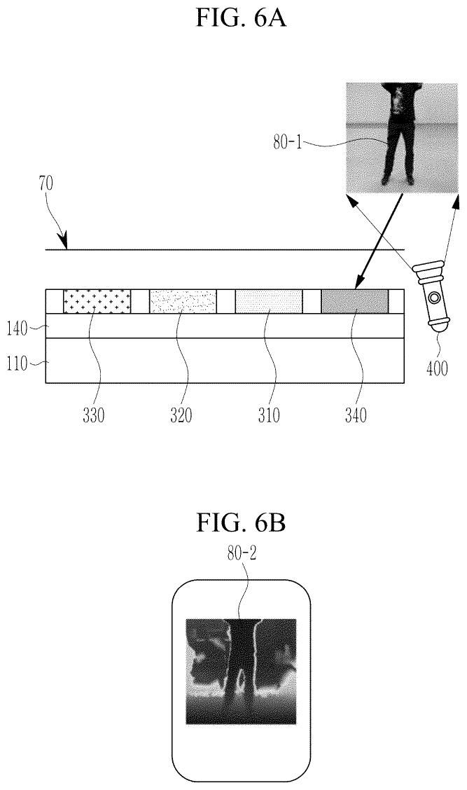

FIGS. 6A and 6B are schematic views showing an example of a distance sensor using the quantum dot display panels of FIGS. 1 and 2.

Referring to FIGS. 6A and 6B, light irradiated by a light source 400 is reflected by a subject 80-1 located at a predetermined distance from the light source 400, and the reflected light may be detected by a quantum dot sensor 340. By measuring the distance and/or time it takes for light irradiated from a light source 400 to be reflected from a subject 80-1 and return to a quantum dot sensor 340, information and changes in the subject 80-1 may be confirmed as an image 80-2. Herein, the light source 400 may irradiate light in the infrared wavelength region, for example, and the quantum dot sensor 340 may be an indirect time-of-flight (iToF) sensor.

The light source 400 may be adjacent to the quantum dot sensor 340, such as being within the quantum dot display panel 1000 or outside thereof. The light source 400 may be positioned relative to the subject 80-1 such that light from the light source 400 is reflected to the quantum dot display panel 1000, to be input to the quantum dot sensor 340. As shown in FIG. 6B, the confirmed image may be a visual representation of the subject 80-1 which is displayed on the quantum dot display panel 1000, etc. without being limited thereto.

As described above, the quantum dot display panel 1000 according to an embodiment may perform both a self-luminous display function and a user interaction function due to stimulus detection, by including a quantum dot light emitting diode including a quantum dot having luminescence characteristics and a quantum dot sensor 340 including a quantum dot having light-absorption characteristics, and thus may be efficient.

In addition, by using a quantum dot light emitting diode as a light source for operating a quantum dot sensor 340, there may be no need to provide a separate light source, and thus a lightweight and thin display panel may be implemented. In addition, the first, second, and/or third quantum dot light emitting diodes may be selectively used depending on the purpose of the quantum dot sensor 340, thereby expanding the scope of application of the quantum dot sensor 340.

In addition, the quantum dot display panel 1000 according to an embodiment may form first, second, and third quantum dot light emitting diodes 310, 320, and 330 and a quantum dot sensor 340 on the substrate 110 using a common process, and may commonly use a first common auxiliary layer 380, a second common auxiliary layer 390, and/or a common electrode 360, thereby simplifying the process and structure.

Hereinafter, a quantum dot display panel 1000 according to an embodiment is described.

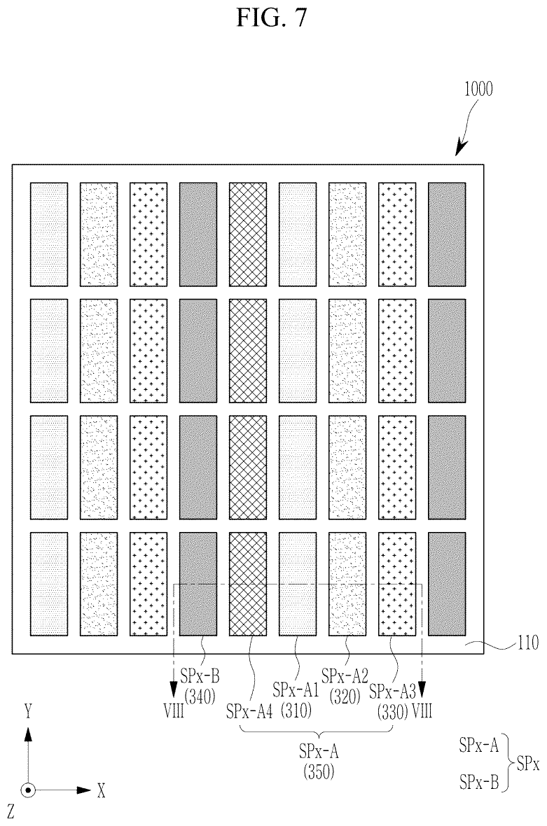

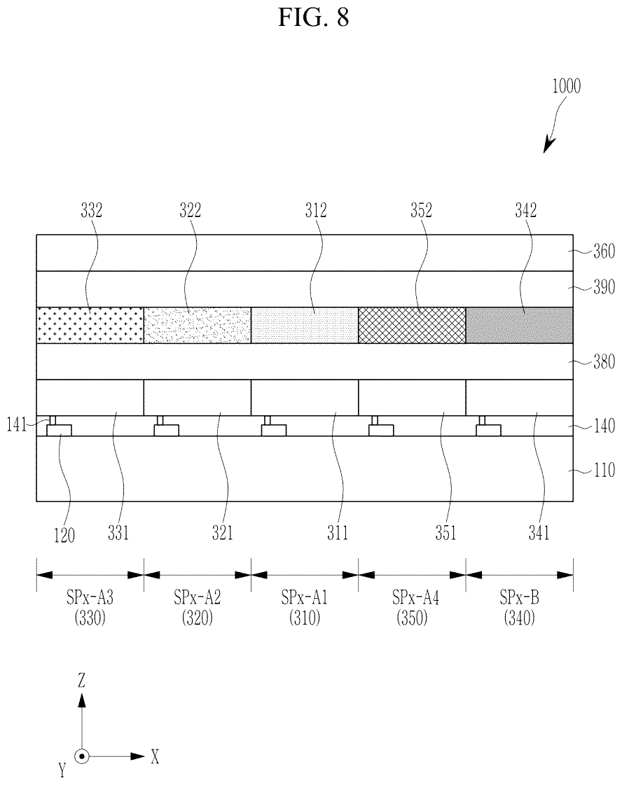

FIG. 7 is a plan view schematically showing another example of a quantum dot display panel 1000 according to an embodiment, and FIG. 8 is a cross-sectional view taken along line VIII-VIII of the quantum dot display panel 1000 of FIG. 7.

Referring to FIGS. 7 and 8, the quantum dot display panel 1000 according to the present embodiment includes a first sub-pixel SPx-A1 for displaying red, a second sub-pixel SPx-A2 for displaying green, a third sub-pixel SPx-A3 for displaying blue, and a fourth sub-pixel SPx-B for detecting light, where the first sub-pixel SPx-A1 includes a first quantum dot light emitting diode 310, the second sub-pixel SPx-A2 includes a second quantum dot light emitting diode 320, the third sub-pixel SPx-A3 includes a third quantum dot light emitting diode 330, and the fourth sub-pixel SPx-B includes a quantum dot sensor 340, similarly to the aforementioned embodiment.

However, unlike the aforementioned embodiment, the quantum dot display panel 1000 according to the present embodiment may further include a fifth sub-pixel SPx-A4 as one of the display sub-pixels SPx-A, and the fifth sub-pixel SPx-A4 may include a fourth quantum dot light emitting diode 350 which emits light in the infrared wavelength region.

The fourth quantum dot light emitting diode 350 is electrically connected to the sub-pixel circuit portion 120 included in the fifth sub-pixel SPx-A4 and may be driven independently. The fourth quantum dot light emitting diode 350 is arranged parallel to the first, second, and third quantum dot light emitting diodes 310, 320, and 330 and the quantum dot sensor 340 along the in-plane direction (e.g., XY direction) of the substrate 110.

The fourth quantum dot light emitting diode 350 includes a pixel electrode 351, a fifth quantum dot layer 352, a common electrode 360, a first common auxiliary layer 380, and a second common auxiliary layer 390 on a substrate 110. The pixel electrode 351 is electrically connected to the sub-pixel circuit portion 120 included in the fifth sub-pixel SPx-A4, and the specific configuration is as described above. The configurations of the common electrode 360, the first common auxiliary layer 380, and the second common auxiliary layer 390 are as described above.

The fifth quantum dot layer 352 may be disposed between the pixel electrode 351 and the common electrode 360 and may be arranged parallel to the first, second, third, and fourth quantum dot layers 312, 322, 332, and 342 along the in-plane direction (e.g., XY direction) of the substrate 110. The fifth quantum dot layer 352 may emit light in at least a portion of an infrared wavelength region, for example, the peak emission wavelength (A_{peak,L}) of the fifth quantum dot layer 352 may fall within a range of about 750 nm to about 3000 nm, and within this range may fall within a range of about 750 nm to about 2500 nm, about 780 nm to about 2000 nm, or about 800 nm to about 1800 nm.

The quantum dot sensor 340 may detect light in at least a portion of the visible to infrared wavelength region as described above, but may, for example detect light in at least a portion of the infrared wavelength region. For example, the absorption wavelength of the fourth quantum dot layer 342 of the quantum dot sensor 340 may include at least a portion of about 750 nm to about 3000 nm, and within that range may include at least a portion of about 750 nm to about 2500 nm, about 780 nm to about 2000 nm, or about 800 nm to about 1800 nm. The wavelength region of light which may be absorbed (detected) by the fourth quantum dot layer 342 included in the quantum dot sensor 340 may at least partially overlap with the wavelength region of light emitted from the fifth quantum dot layer 352.

The fourth quantum dot light emitting diode 350 may be used as a light source for the quantum dot sensor 340, and may supply light in the infrared wavelength region emitted from the fourth quantum dot light emitting diode 350 to an object such as a user's recognition target or subject, and detect light reflected from the object by the quantum dot sensor 340.

Hereinafter, a quantum dot display panel 100 according to an embodiment is described.

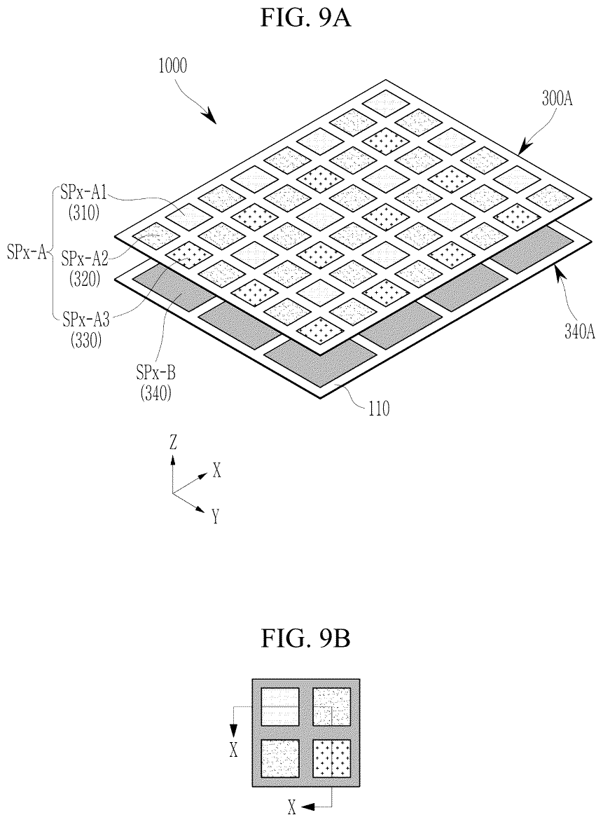

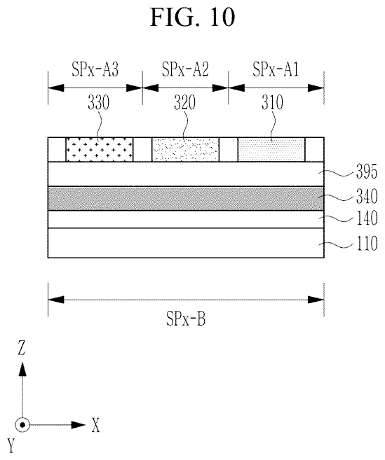

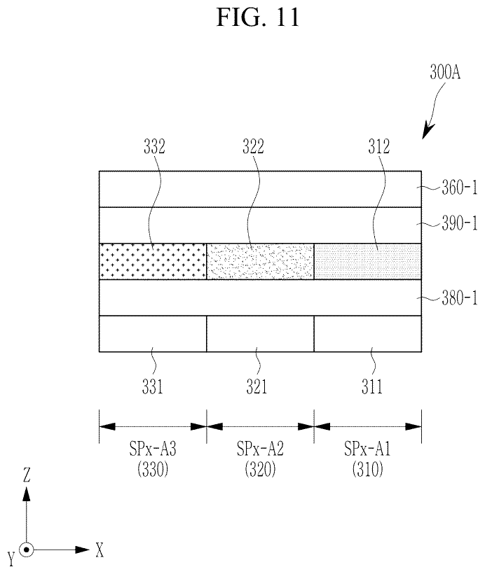

FIGS. 9A and 9B are plan views schematically showing an example of a quantum dot display panel 1000 according to an embodiment, FIG. 10 is a cross-sectional view taken along the line X-X of the quantum dot display panel 1000 of FIG. 9B, FIG. 11 is a cross-sectional view showing an example of a quantum dot light emitting diode array in the quantum dot display panels of FIGS. 9A, 9B and 10, and FIG. 12 is a cross-sectional view showing an example of a quantum dot sensor array in the quantum dot display panels of FIGS. 9A, 9B and 10.

Referring to FIGS. 9A, 9B and 10, the quantum dot display panel 1000 according to the present embodiment includes a first sub-pixel SPx-A1 for displaying red, a second sub-pixel SPx-A2 for displaying green, and a third sub-pixel SPx-A3 for displaying blue, where the first sub-pixel SPx-A1 includes a first quantum dot light emitting diode 310, the second sub-pixel SPx-A2 includes a second quantum dot light emitting diode 320, and the third sub-pixel SPx-A3 includes a third quantum dot light emitting diode 330, similar to the aforementioned embodiment. Additionally, the quantum dot display panel 1000 according to the present embodiment includes a quantum dot sensor 340 similar to the aforementioned embodiment.

However, unlike the above-described example, the quantum dot display panel 1000 according to the present embodiment has a quantum dot sensor 340 which is not arranged parallel to the first, second, and third quantum dot light emitting diodes 310, 320, and 330, but is stacked on top of each other.

For example, a quantum dot display panel 1000 includes a quantum dot sensor array 340A including a plurality of quantum dot sensors 340, and a quantum dot light emitting diode array 300A disposed on the quantum dot sensor array 340A and including first, second, and third quantum dot light emitting diodes 310, 320, and 330.

A first quantum dot sensor layer having the plurality of quantum dot sensors 340 may overlap a second quantum dot sensor layer having the first, second, and third quantum dot light emitting diodes 310, 320, and 330. As being overlapping, elements may be disposed along a same line in a direction, such as along a thickness direction, a lateral direction, etc. For example, one element may be above or below another element along a thickness direction, so as to be be considered overlapping each other, without being limited thereto. A thickness direction may be defined along a Z direction as a third direction, which crosses a plane defined by the X direction and a Y direction (variously first and second directions).

The quantum dot light emitting diode array 300A includes first, second, and third quantum dot light emitting diodes 310, 320, and 330 arranged in a parallel manner along an in-plane direction (e.g., XY direction) of a substrate 110. The quantum dot sensor array 340A includes a plurality of quantum dot sensors 340 arranged side by side along an in-plane direction (e.g., XY direction) of a substrate 110. Each quantum dot sensor 340 may overlap with at least one of the first, second, and third quantum dot light emitting diodes 310, 320, and 330 along the thickness direction (e.g., Z direction) of the substrate 110, and may overlap with two or more of the first, second, and third quantum dot light emitting diodes 310, 320, and 330.

An optical filter 395 may be further included between the quantum dot light emitting diode array 300A and the quantum dot sensor array 340A. The optical filter 395 may block light entering the quantum dot sensor array 340A other than light having a wavelength region which may be detected by the quantum dot sensor 340.

Referring to FIG. 11, the first, second, and third quantum dot light emitting diodes 310, 320, and 330 of the quantum dot light emitting diode array 300A each include pixel electrodes 311, 321, and 331, a first (upper) common auxiliary layer 380-1, a first, second or third quantum dot layer 312, 322, and 332, a second (upper) common auxiliary layer 390-1 and a (first) common electrode 360-1, as described above.

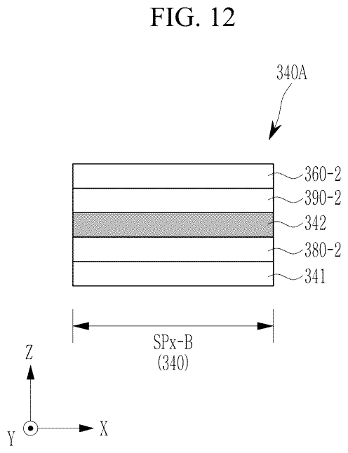

Referring to FIG. 12, the quantum dot sensor 340 of the quantum dot sensor array 340A includes a pixel electrode 341, a fourth quantum dot layer 342, a (second) common electrode 360-2, and first and second (lower) charge auxiliary layers 380-2 and 390-2, and the pixel electrode 341, the fourth quantum dot layer 342, and the common electrode 360-2 are each the same as described above. The first and second charge auxiliary layers 380-2 and 390-2 may be the same as or different from the first and second common auxiliary layers 380-1 and 390-1 described above. The first and second charge auxiliary layers 380-2 and 390-2 may include a charge transport material which may match the energy level of the light-absorbing quantum dot included in the fourth quantum dot layer 342. The fourth quantum dot layer 340 may overlap with the first, second, and/or third quantum dot layers 312, 322, and 332 along the thickness direction (e.g., Z direction) of the substrate 110. Only one pattern of the fourth quantum dot layer 340 may overlap with all of the first, second, and/or third quantum dot layers 312, 322, and 332 along the thickness direction (e.g., Z direction) of the substrate 110.

Referring to FIGS. 9A and 9B, quantum dot patterns may be spaced apart from each other along the in-plane direction by a separation pattern, such as a pixel defining layer, without being limited thereto. The separation pattern may be coplanar with quantum dot patterns of a respective array layer. Separation patterns in respective array layers may overlap each other, without being limited thereto. A planar area of the respective array layers may include an active area where sub-pixels areas are defined, and a non-active area which is between the sub-pixel areas. The non-active area may not contribute to an emission or detection function, without being limited thereto.

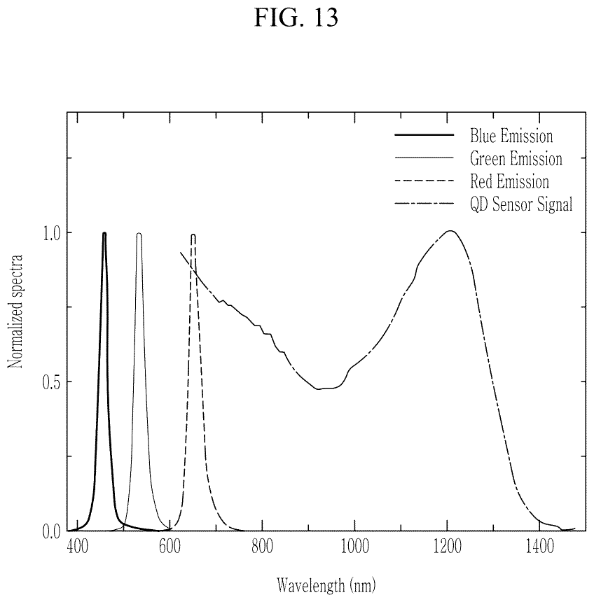

FIG. 13 is an optical spectrum showing an example of the luminescence and light-absorption characteristics of the quantum dot light emitting diode array 300A and the quantum dot sensor array 340A in the quantum dot display panels of FIGS. 9A, 9B and 10.

Referring to FIG. 13, the quantum dot light emitting diode array 300A may emit light in red, green, and blue wavelength regions, each having a relatively narrow FWHM, and the quantum dot sensor array 340A may absorb light in the red wavelength region to the infrared wavelength region. Unlike the embodiments described above, the quantum dot sensor 340 is disposed under the first, second, and third quantum dot light emitting diodes 310, 320, and 330 and thus may absorb light in a relatively long wavelength region.

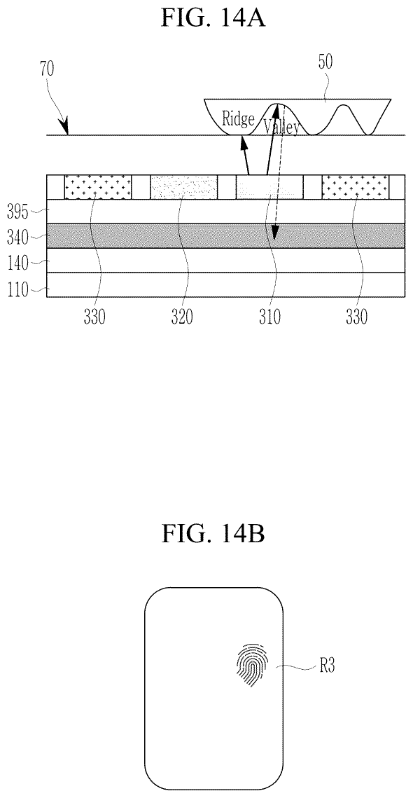

FIGS. 14A and 14B are schematic views showing an example of a fingerprint sensor using the quantum dot display panel 1000 of FIGS. 10 and 11.

Referring to FIGS. 14A and 14B, when a finger is brought into contact with the quantum dot display panel 1000 (including the upper substrate 70), the fingerprint 50 has a height difference between the ridge, which is a protruding portion, and the valley, which is a concave portion, and the light reflected from the fingerprint 50 may be distinguished by this height difference. For example, the ridge of the fingerprint 50 may be in close contact with the quantum dot display panel 1000 (e.g., upper substrate 70) so that little or no light is reflected from the fingerprint 50, and the valley of the fingerprint 50 may not be in close contact with the quantum dot display panel 1000 (e.g., upper substrate 70) and air may be included therein so that relatively more light is reflected from the fingerprint 50. For example, when the first quantum dot light emitting diode 310 which emits light in the red wavelength region is used as a light source, the amount of light absorbed by the quantum dot sensor 340 may vary depending on the difference in the amount of light reflected between the ridge and valley of the fingerprint 50, and information obtained from this difference in the amount of light may be converted into an electrical signal to obtain an image of the fingerprint 50. However, the present disclosure is not limited thereto, and one, two, or three of the first, second, and/or third quantum dot light emitting diodes 310, 320, and 330 may be selected and used as a light source depending on the intended use.

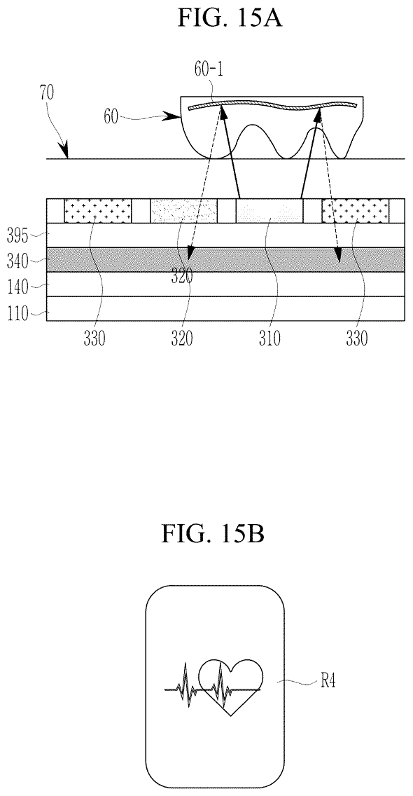

As shown in FIGS. 14B and 15B, the image R3 and R4 may represent a relative location of the fingerprint 50 or the part of the living body across the in-plane direction (e.g., XY direction) of the upper substrate 70, a visual representation of the the fingerprint 50 or the part of the living body as a display of the quantum dot display panel 1000, etc. without being limited thereto.

FIGS. 15A and 15B are schematic views showing an example of a biometric signal detection sensor using the quantum dot display panel 100 of FIGS. 10 and 11.

Referring to FIGS. 15A and 15B, when a living body (e.g., wrist or chest) 60 is placed on the quantum dot display panel 1000 (including the upper substrate 70) and light is irradiated from the first quantum dot light emitting diode 310, light reflected by a blood vessel 60-1 is detected by the quantum dot sensor 340 of the quantum dot sensor array 340A and converted into an electrical signal, thereby obtaining a biometric signal. However, the present disclosure is not limited thereto, and one, two, or three of the first, second, and/or third quantum dot light emitting diodes 310, 320, and 330 may be selected and used as a light source depending on the intended use.

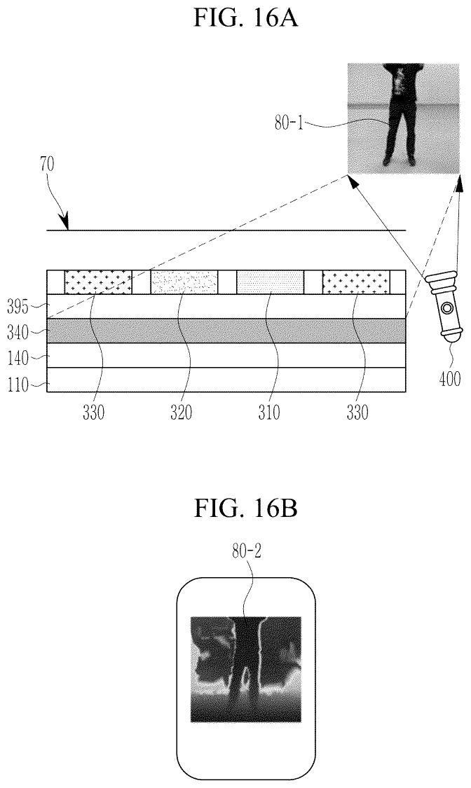

FIGS. 16A and 16B are schematic views showing an example of a distance sensor using the quantum dot display panels of FIGS. 10 and 11.

Referring to FIGS. 16A and 16B, light irradiated by a light source 400 is reflected by a subject 80-1 disposed at a predetermined distance from the light source 400, and the reflected light may be detected by a quantum dot sensor 340. By measuring the distance and/or time it takes for light irradiated from a light source 400 to be reflected from a subject 80-1 and return to a quantum dot sensor 340, information and changes 80-2 of the subject 80-1 may be confirmed as an image. Herein, the light source 400 may irradiate light in the infrared wavelength region, for example, and the quantum dot sensor 340 may be an indirect time-of-flight (iToF) sensor.

Hereinafter, a quantum dot display panel according to an embodiment is described.

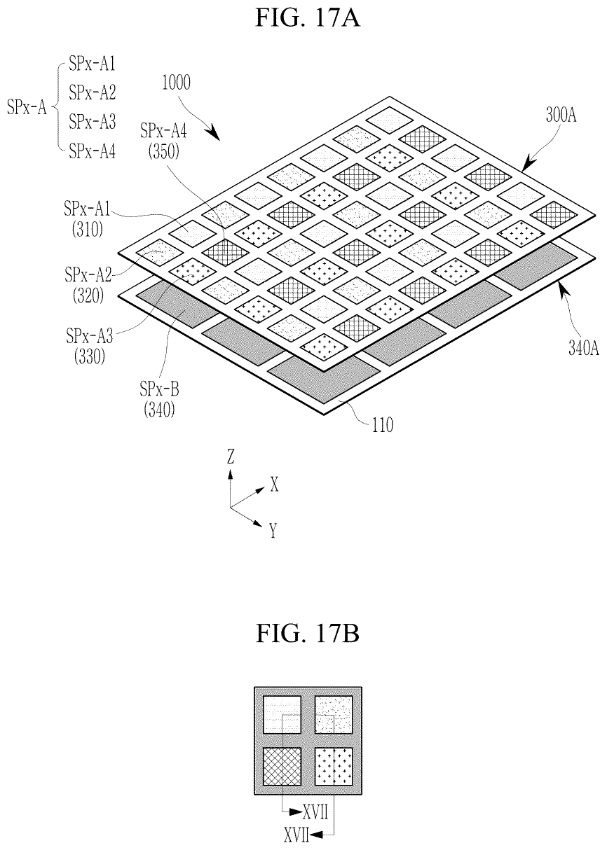

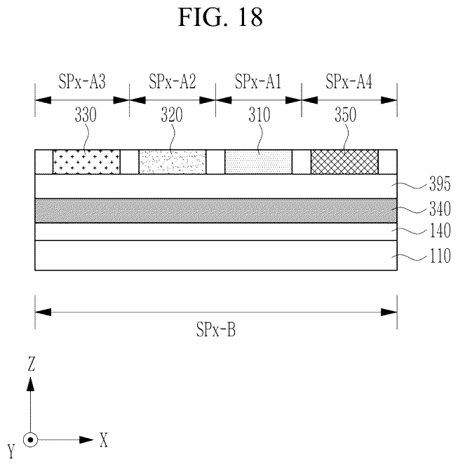

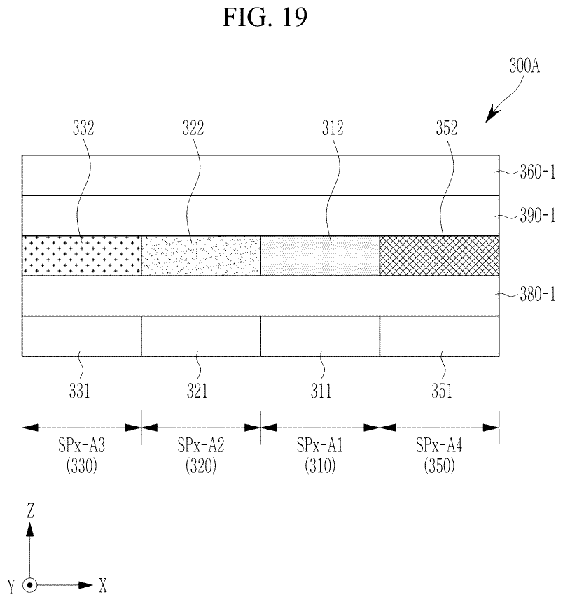

FIGS. 17A and 17B are plan views schematically showing an example of a quantum dot display panel 1000 according to an embodiment, FIG. 18 is a cross-sectional view taken along line XVIII-XVIII of the quantum dot display panel of FIG. 17B, and FIG. 19 is a cross-sectional view showing an example of a quantum dot light emitting diode array 300a in the quantum dot display panels of FIGS. 17A, 17B and 18.

Referring to FIGS. 17A, 17B and 18, the quantum dot display panel 1000 according to the present embodiment includes a quantum dot sensor array 340A including a plurality of quantum dot sensors 340, and a quantum dot light emitting diode array 300A disposed on the quantum dot sensor array 340A and including first, second, and third quantum dot light emitting diodes 310, 320, and 330, similarly to the aforementioned embodiment.

However, the quantum dot display panel 1000 according to the present embodiment may further include a fifth sub-pixel SPx-A4 as one of the display sub-pixels SPx-A in the quantum dot light emitting diode array 300A, and the fifth sub-pixel SPx-A4 may include a fourth quantum dot light emitting diode 350 which emits light in the infrared wavelength region.

The fourth quantum dot light emitting diode 350 is electrically connected to the sub-pixel circuit portion 120 included in the fifth sub-pixel SPx-A4 and may be driven independently. The fourth quantum dot light emitting diode 350 is arranged parallel to the first, second, and third quantum dot light emitting diodes 310, 320, and 330 along the in-plane direction (e.g., XY direction) of the substrate 110.

Referring to FIG. 19, the fourth quantum dot light emitting diode 350 includes a pixel electrode 351, a fifth quantum dot layer 352, a common electrode 360-1, a first common auxiliary layer 380-1, and a second common auxiliary layer 390-1, the specific descriptions of which are as described above.

The quantum dot sensor 340 is as illustrated in FIG. 12. The quantum dot sensor 340 may detect light in at least a portion of the visible to infrared wavelength region as described above, but may, for example, detect light in at least a portion of the infrared wavelength region. For example, the absorption wavelength of the fourth quantum dot layer 342 of the quantum dot sensor 340 may include at least a portion of about 750 nm to about 3000 nm, and within that range may include at least a portion of about 750 nm to about 2500 nm, about 780 nm to about 2000 nm, or about 800 nm to about 1800 nm. The wavelength region of light which may be absorbed (detected) by the fourth quantum dot layer 342 included in the quantum dot sensor 340 may at least partially overlap with the wavelength region of light emitted from the fifth quantum dot layer 352.

The fourth quantum dot light emitting diode 350 may be used as a light source for the quantum dot sensor 340, and may supply light in the infrared wavelength region emitted from the fourth quantum dot light emitting diode 350 to an object such as a user's recognition target or subject, and detect light reflected from the object by the quantum dot sensor 340.

The quantum dot display panel 1000 may be applied to various electronic devices including display devices, and for example, may be applied to display devices such as TVs, monitors, computers, tablet PCs, and mobile phones, medical devices, security devices, or lighting devices such as light sources.

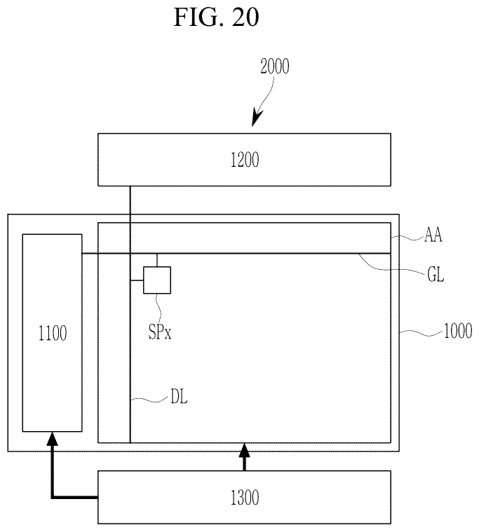

FIG. 20 is a block diagram showing an example of an electronic device 2000 according to an embodiment.

Referring to FIG. 20, an electronic device 2000 according to an embodiment includes a quantum dot display panel 1000, a gate driver 1100, a data driver 1200, and a power voltage generator 1300. The quantum dot display panel 1000 includes a display area AA which displays an image and a peripheral area excluding the display area AA. Where a planar area of the quantum dot display panel 1000 is defined, sch as by a substrate 110 or the like, an area adjacent to and excluding the display area AA may be a non-display area, without being limited thereto.

The quantum dot display panel 1000 includes a plurality of gate lines GL, a plurality of data lines DL, and a plurality of sub-pixels SPx electrically connected to the gate lines GL and the data lines DL. The gate lines GL may extend along a first direction and the data lines DL may extend along a second direction which intersects the first direction. The plurality of sub-pixels SPx may include a display sub-pixel SPx-A and a sensing sub-pixel SPx-B as described above, and each sub-pixel SPx may receive (electrical) signals from the gate lines GL and the data lines DL and operate independently. Each sub-pixel SPx of the quantum dot display panel 1000 includes first, second, and third quantum dot light emitting diodes 310, 320, and 330 or quantum dot sensors 340, the descriptions of which are as described above.

The gate driver 1100 may generate a gate signal for driving a gate line GL in response to a first control signal received from a driving control unit (not shown) and output the generated gate signal to the quantum dot display panel 1000 through the gate line GL.

The data driver 1200 may receive a second control signal and a data signal from a driving control unit (not shown) and output the received data signal to the quantum dot display panel 1000 through a data line DL.

The power voltage generator 1300 may generate a gate driving voltage for driving the gate driver 1100 and output it to the gate driver 1100, and may generate a data driving voltage for driving the data driver 1200 and output it to the data driver 1200.

The electronic device 2000 may additionally include a light source. The light source may be disposed outside the quantum dot display panel 1000. The light source may, for example, supply light in the infrared wavelength region, and may be the light source 400 shown in FIG. 6A or 16A and may be used in an indirect time-of-flight (iToF) sensor.

An electronic device 2000 according to an embodiment may perform both a self-luminous display function and a user interaction function by stimulus detection as described above, and may operate the quantum dot light emitting diodes 310, 320, and 330 and quantum dot sensor 340 for the self-luminous display function simultaneously or sequentially.

A method of operating an electronic device 2000 according to an embodiment includes driving at least one of a first quantum dot light emitting diode 310, a second quantum dot light emitting diode 320, and a third quantum dot light emitting diode 330, and driving a quantum dot sensor 340, where the driving of at least one of the first, second, and third quantum dot light emitting diodes 310, 320, and 330 and the driving of the quantum dot sensor 340 may be performed simultaneously or sequentially.

For example, an electronic device 2000 according to an embodiment may perform a self-luminous display function and a function of detecting a target. As illustrated in FIGS. 4A and 4B or 14A and 14B, the driving of at least one of the first, second, and/or third quantum dot light emitting diodes 310, 320, and 330 may include supplying light emitted from the first, second, and/or third quantum dot layers 312, 322, and 332 to the target (e.g., a fingerprint) 50, and driving the quantum dot sensor 340 may include detecting light reflected by the target. Additionally, the method may further include comparing an image (information) of a target (e.g., a fingerprint 50) detected by a quantum dot sensor 340 with a previously stored contrast image, and driving at least one of the first, second, and third quantum dot light emitting diodes 310, 320, and 330 to display an image if the image of the target and the contrast image match.

For example, an electronic device 2000 according to an embodiment may perform a self-luminous display function and a biometric signal detection function, and as illustrated in FIGS. 5A and 5B or 15A and 15B, the driving of at least one of the first, second, and third quantum dot light emitting diodes 310, 320, and 330 may include irradiating light emitted from the first, second, and/or third quantum dot layers 312, 322, and 332 onto a living body 60, and the driving of the quantum dot sensor 340 may include detecting light reflected by the living body 60 and converting the detected light into an electrical signal.

For example, an electronic device 2000 according to an embodiment may perform a self-luminous display function and a function of detecting distance and/or movement from indirect time-of-flight (iToF) measurement, and may include turning on a light source 400 which irradiates light in an infrared wavelength region to irradiate light to a subject 80-1, as illustrated in FIG. 6A or 16A, measuring a time or distance for the irradiated light to be reflected by the subject 80-1 and detected by a quantum dot sensor 340, and driving at least one of the first, second, and third quantum dot light emitting diodes 310, 320, and 330 based on the measured time or distance to display information and changes of the subject 80-1 as an image 80-2.

Referring to FIG. 20, for example, an electronic device 2000 may include one or more of a processor, a memory device, a storage device, an input/output (“I/O”) device, a power supply, and a display panel. Here, the display panel may correspond to the quantum dot display panel.

The processor may perform various computing functions. In an embodiment, the processor may be a microprocessor, a central processing unit (“CPU”), an application processor (“AP”), or the like.

The memory device may store data for operations of the electronic device 2000. The memory device may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

The storage device may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply may provide power for operations of the electronic device 2000. The power supply may provide power to the display panel. The display panel may be coupled to other components via the buses or other communication links. In an embodiment, the display panel may be included in the I/O device.

A method of operating an electronic device 2000 may include driving a quantum dot light emitting diode of a quantum dot display panel of the electronic device to emit light, the quantum dot light emitting diode including a quantum dot layer emitting light in a red, green or blue wavelength range, and driving a quantum dot sensor of the quantum dot display panel to sense light, the quantum dot sensor including a quantum dot layer absorbing light in at least a portion of a visible wavelength range to an infrared wavelength region. The driving of the quantum dot light emitting diode and the driving of the quantum dot sensor are performed simultaneously or sequentially, by a driver of the electronic device.

The driving of the quantum dot light emitting diode may include supplying light to a target which is positioned relative to the electronic device and reflects the light, and the driving of the quantum dot sensor may include sensing the light which is reflected by the target. Here, the method may further include generating an image of the target by the sensing of the light and comparing the image with a contrast image, by a processor of the electronic device, and driving the quantum dot light emitting diode by the processor, to display a target image if the image of the target matches the contrast image.

The method may include turning on a light source of the electronic device, to supply light in the infrared wavelength range, to a subject, and measuring a time or distance for the light which is supplied by the light source to be reflected by the subject.and detected by the quantum dot sensor, by a processor of the electronic device Hereinafter, the embodiments are illustrated in more detail with reference to examples. However, these examples are exemplary, and the scope of claims is not limited thereto.

### EXAMPLES

### Example 1

Surface treatment with UV-ozone is performed for 15 minutes on a glass substrate on which ITO (WF: 4.8 eV, anode) is deposited. A PEDOT:PSS solution is spin-coated on the anode, heat-treatment is performed in an air atmosphere at 150° C. for 10 minutes, and then heat-treatment is performed again in a N₂ atmosphere at 150° C. for 30 minutes to form a 30 nm-thick lower hole auxiliary layer (HOMO: 5.35 eV, LUMO: 2.75 eV). Subsequently, on the lower hole auxiliary layer, a poly[(9,9-dioctylfluorenyl-2,7-diyl-co-(4,4′-(N-4-butylphenyl)diphenylamine]solution (TFB) (Sumitomo) is spin-coated and heat-treated at 150° C. for 30 minutes to form a 20 nm-thick upper hole auxiliary layer (HOMO: 5.35 eV, LUMO: 3.00 eV). Then, an InP quantum dot dispersion is spin-coated on the upper hole auxiliary layer and heat-treated at 80° C. for 30 minutes to form a 20 nm thick quantum dot emitting layer (HOMO: 5.55 eV, LUMO: 3.58 eV). Then, a Zn_{0.85}Mg_{0.15}O nanoparticle dispersion is spin-coated on the quantum dot emitting layer and heat-treated at 80° C. for 30 minutes to form a 40 nm-thick electron auxiliary layer (HOMO: 7.6 eV, LUMO: 4.3 eV). Then, 100 nm of aluminum (Al) is vacuum-deposited on the electron auxiliary layer to form a cathode (WF: 4.3 eV), thereby manufacturing a quantum dot light emitting diode.

### Example 2

A quantum dot sensor is manufactured in the same manner as in Example 1, except that an InAs quantum dot dispersion is spin-coated and heat-treated at 80° C. for 30 minutes to form a 100 nm-thick quantum dot absorbing layer (HOMO: 5.2 eV, LUMO: 4.23 eV), instead of the quantum dot emitting layer.

### Evaluation

The electrical properties and luminescence characteristics of quantum dot light emitting diode according to Example 1 and the quantum dot sensor according to Example 2 are evaluated.

Electrical properties and luminescence characteristics are measured using a current-voltage-luminance measuring device (Keithley 2200, Minolta CS200).

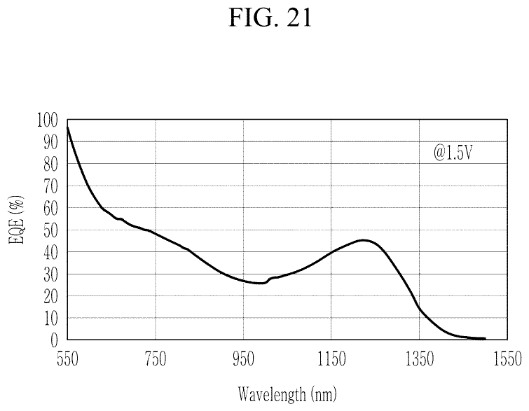

The results are shown in Table 1 and FIG. 21.

FIG. 21 is a graph showing external quantum efficiency in percent (EQE %) according to wavelength of a quantum dot sensor in nanometers (nm) according to Example 2. A voltage of 1.5 volts (V) is referenced.

TABLE 1

| | λ_{peak, L} | EQEₘₐₓ | Lumₘₐₓ |
|---|---|---|---|
| Example 1 | 629 nm | 19.5% | 96,425 Cd/m² |

Referring to Table 1 and FIG. 21, the quantum dot light emitting diode according to Example 1 and the quantum dot sensor according to Example 2 have a common structure other than the quantum dot light emitting layer and the quantum dot light absorbing layer, and exhibit good electrical properties. From this, it may be expected that quantum dot light emitting diodes and quantum dot sensors may be manufactured into a single quantum dot display panel through a common process to perform a multi-functional display panel exhibiting good electrical performance.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A quantum dot display panel, comprising:
a first quantum dot light emitting diode including a first quantum dot layer emitting light in a red wavelength range,
a second quantum dot light emitting diode including a second quantum dot layer emitting light in a green wavelength range,
a third quantum dot light emitting diode including a third quantum dot layer emitting light in a blue wavelength range, and
a quantum dot sensor including a fourth quantum dot layer absorbing light in at least a portion of a visible wavelength range to an infrared wavelength range.

2. The quantum dot display panel of claim 1, further comprising a substrate,
wherein the first, second and third quantum dot light emitting diodes and the quantum dot sensor are coplanar with each other along the substrate.

3. The quantum dot display panel of claim 2, wherein
the first, second and third quantum dot light emitting diodes further comprise a first, second and third pixel electrode respectively under the first, second and third quantum dot layer,
the quantum dot sensor further comprises a fourth pixel electrode under the fourth quantum dot layer,
each of the first, second and third quantum dot light emitting diodes and the quantum dot sensor further comprises a common electrode on the first, second, third and fourth quantum dot layers,
the first, second, third and fourth pixel electrodes are coplanar with each other along the substrate, and
the first, second, third and fourth quantum dot layers are coplanar with each other along the substrate.

4. The quantum dot display panel of claim 3, wherein
the common electrode is extended continuously along each of the first, second and third quantum dot light emitting diodes and the quantum dot sensor, and
each of the first, second and third quantum dot light emitting diodes and the quantum dot sensor further comprises:
a first common auxiliary layer extended continuously between the first, second, third, and fourth pixel electrodes and the first, second, third and fourth quantum dot layers, respectively, and
a second common auxiliary layer extended continuously between the common electrode, and each of the first, second, third, and fourth quantum dot layers.

5. The quantum dot display panel of claim 4, wherein the second common auxiliary layer comprises inorganic nanoparticles represented by Zn₁₋ₓQₓO, where Q is Be, Mg, Ca, Ba, Sr, Ra or a combination thereof, and 0≤x<0.5.

6. The quantum dot display panel of claim 2, wherein the quantum dot display panel comprises:
first sub-pixels which display red light, each of the first sub-pixels including the first quantum dot light emitting diode,
second sub-pixels which display green light, each of the second sub-pixels including the second quantum dot light emitting diode,
third sub-pixels which display blue light, each of the third sub-pixels including the third quantum dot light emitting diode,
fourth sub-pixels which sense light, each of the fourth sub-pixels including the quantum dot sensor,
unit groups each comprising at least one of the first sub-pixels, at least one of the second sub-pixels and at least one of the third sub-pixels, the unit groups arranged coplanar with each other along the substrate, and
a portion of the unit groups further comprising at least one of the fourth sub-pixels.

7. The quantum dot display panel of claim 1, further comprising a fourth quantum dot light emitting diode including a fifth quantum dot layer emitting light in the infrared wavelength range.

8. The quantum dot display panel of claim 1, further comprising:
a quantum dot sensor array including the quantum dot sensor provided in plural defining a plurality of the quantum dot sensors, and
a quantum dot light emitting diode array including each of the first, second and third quantum dot light emitting diodes provided in plural defining a plurality of the first, second and third quantum dot light emitting diodes,
wherein the quantum dot sensor array and the quantum dot light emitting diode array are stacked on each other.

9. The quantum dot display panel of claim 8, further comprising a substrate supporting the quantum dot light emitting diode array,
wherein
the first, second and third quantum dot light emitting diodes further comprise:
a first, second and third pixel electrode respectively under the first, second and third quantum dot layer, and
a first common electrode on the first, second and third quantum dot layer,
wherein the quantum dot sensor further comprises:
a fourth pixel electrode under the fourth quantum dot layer, and
a second common electrode on the fourth quantum dot layer, and
wherein the fourth quantum dot layer overlaps with the first, second or third quantum dot layer along a thickness direction of the substrate.

10. The quantum dot display panel of claim 8, wherein the fourth quantum dot layer is configured to detect light of a red wavelength range to the infrared wavelength range.

11. The quantum dot display panel of claim 8, wherein the quantum dot light emitting diode array further comprises a fourth quantum dot light emitting diode including a fifth quantum dot layer emitting light in the infrared wavelength range.

12. The quantum dot display panel of claim 8, further comprising an optical filter between the quantum dot light emitting diode array and the quantum dot sensor array.

13. The quantum dot display panel of claim 1, wherein the quantum dot sensor comprises a fingerprint sensor, a biometric signal detection sensor, a bioimaging sensor, a distance sensor, a motion sensor or a combination thereof.

14. An electronic device, comprising:
a quantum dot display panel,
a gate driver configured to generate a gate signal and output the gate signal to the quantum dot display panel, and
a data driver configured to output a data voltage to the quantum dot display panel,
wherein the quantum dot display panel comprises:
a first quantum dot light emitting diode including a first quantum dot layer emitting light in a red wavelength range,
a second quantum dot light emitting diode including a second quantum dot layer emitting light in a green wavelength range,
a third quantum dot light emitting diode including a third quantum dot layer emitting light in a blue wavelength range, and
a quantum dot sensor including a fourth quantum dot layer absorbing light in at least a portion of a visible wavelength range to infrared wavelength range.

15. The electronic device of claim 14, wherein
the first, second and third quantum dot light emitting diodes and the quantum dot sensor are coplanar with each other, or
the quantum dot sensor overlaps with the first, second or third quantum dot light emitting diode along a thickness direction of the quantum dot display panel.

16. The electronic device of claim 14, further comprising a light source which supplies light in the infrared wavelength range.

17. A method of operating an electronic device, the method comprising:
driving a quantum dot light emitting diode of a quantum dot display panel of the electronic device to emit light, the quantum dot light emitting diode including a quantum dot layer emitting light in a red, green or blue wavelength range, and
driving a quantum dot sensor of the quantum dot display panel to sense light, the quantum dot sensor including a quantum dot layer absorbing light in at least a portion of a visible wavelength range to an infrared wavelength region,
wherein the driving of the quantum dot light emitting diode and the driving of the quantum dot sensor are performed simultaneously or sequentially, by a driver of the electronic device.

18. The method of claim 17, wherein
the driving of the quantum dot light emitting diode comprises supplying light to a target which is positioned relative to the electronic device and reflects the light, and
the driving of the quantum dot sensor comprises sensing the light which is reflected by the target.

19. The method of claim 18, further comprising:
generating an image of the target by the sensing of the light and comparing the image with a contrast image, by a processor of the electronic device, and
driving the quantum dot light emitting diode by the processor, to display a target image if the image of the target matches the contrast image.

20. The method of claim 17, further comprising:
turning on a light source of the electronic device, to supply light in the infrared wavelength range, to a subject, and
measuring a time or distance for the light which is supplied by the light source to be reflected by the subject and detected by the quantum dot sensor, by a processor of the electronic device.
